(19) United States
(12) Patent Application Publication
(10) Pub. No.: US 2016/0380020 A1
(43) Pub. Date: Dec. 29, 2016

(54) PHOTODETECTOR AND METHOD FOR MANUFACTURING PHOTODETECTOR

(71) Applicant: Kabushiki Kaisha Toshiba, Minato-ku (JP)

(72) Inventors: Yasuharu HOSONO, Kawasaki (JP); Kazuhiro SUZUKI, Minato (JP); Hitoshi YAGI, Yokohama (JP); Kazunori MIYAZAKI, Yokohama (JP); GO KAWATA, Kawasaki (JP); Keita SASAKI, Yokohama (JP); Rei HASEGAWA, Yokohama (JP)

(73) Assignee: Kabushiki Kaisha Toshiba, Minato-ku (JP)

(21) Appl. No.: 15/257,331

(22) Filed: Sep. 6, 2016

Related U.S. Application Data
(63) Continuation of application No. PCT/JP2014/077459, filed on Oct. 15, 2014.

(30) Foreign Application Priority Data
Mar. 20, 2014 (JP) 2014-058931

(51) Int. Cl. H01L 27/146; H01L 31/0216; G01T 1/20; H01L 31/0232

(52) U.S. Cl. CPC H01L 27/14663; H01L 31/02322; H01L 31/02161; H01L 27/14618; H01L 27/14687; H01L 27/14685; H01L 27/14661; G01T 1/2018

(57) ABSTRACT

According to an embodiment, a photodetector includes a photo detection layer, light conversion members, and a first member. The photo detection layer includes, on a light incident surface, plural pixel regions and a surrounding region. The pixel region holds a photo detection element to detect the light. The surrounding region is a region other than the pixel regions on the light incident surface. The light conversion members are arranged to oppose the pixel regions in the photo detection layer and convert radiation to the light. Each light conversion member includes a bottom surface opposing the pixel region in the photo detection layer, a top surface opposing the bottom surface, and a lateral surface connecting the bottom and top surfaces. The first member is disposed on a portion of the surrounding region on the light incident surface and covers a portion of the lateral surface of the light conversion member.

### CROSS-REFERENCE TO RELATED APPLICATION(S)

This application is a continuation of PCT international application Ser. No. PCT/JP2014/077459 filed on Oct. 15, 2014 which designates the United States, and which claims the benefit of priority from Japanese Patent Application No. 2014-058931, filed on Mar. 20, 2014; the entire contents of which are incorporated herein by reference.

### FIELD

Embodiments described herein relate generally to a photodetector and a method for manufacturing the photodetector.

### BACKGROUND

A photodetector such as a silicon photo multiplier (SiPM) in which a plurality of avalanche photo diodes (APDs) is arrayed as photo detection elements has been known. The SiPM takes advantage of an avalanche breakdown to cause the APD to work under a condition of a reverse bias voltage higher than an avalanche breakdown voltage of the APD, thereby driving the APD in a range called a Geiger mode. A gain of the APD during working in the Geiger mode is extremely high ranging from 10⁵ to 10⁶ and thus, even weak light of one photon can be measured.

Meanwhile, a device employing a multi-pixel structure using the plurality of APDs as one pixel and combined with a scintillator that converts an X-ray into light has been disclosed. When the APD and the scintillator are combined with each other, a photon counting image having a spatial resolution in accordance with a size of the scintillator can be acquired. For example, a technique for acquiring a computed tomography (CT) image by detecting the X-ray has been also known.

In order to acquire a higher quality image, a larger number of pixels need to be arranged at a high density. In a manufacturing process for the photodetector, a through electrode called a through silicon via (TSV) electrode needs to be formed. When the through electrode is formed, it is necessary to shape a substrate including the photo detection element into a thin layer of approximately several tens micrometers. In the manufacturing process for the photodetector, in order to prevent damage or the like to the substrate including the photo detection element, a supporting substrate for reinforcement is first bonded thereto and then, processing for the layer thinning, the through electrode, and the like is carried out. Subsequently, after the processing, the supporting substrate is removed.

### BRIEF DESCRIPTION OF THE DRAWINGS

FIG. 1 is a schematic view illustrating an exemplary inspection device;

FIG. 2 is a view illustrating an array state of a photodetector;

FIG. 3 is a plan view of the photodetector;

FIG. 4 is a perspective view of the photodetector;

FIG. 5 is a cross-sectional view taken along line A-A′ in FIG. 3;

FIG. 6A is an enlarged schematic view illustrating a portion of a first member;

FIG. 6B is a schematic view illustrating a configuration with a reflection layer provided on a surface opposing a light conversion member;

FIG. 6C is a schematic view illustrating another mode of the first member;

FIG. 7 is a view of a photodetector;

FIG. 8 is a view of a photodetector;

FIG. 9 is a view of a photodetector;

FIG. 10 is a view of a photodetector;

FIG. 11A is an explanatory view for a method for manufacturing a photodetector;

FIG. 11B is an explanatory view for the method for manufacturing a photodetector;

FIG. 11C is an explanatory view for the method for manufacturing a photodetector;

FIG. 11D is an explanatory view for the method for manufacturing a photodetector;

FIG. 11E is an explanatory view for the method for manufacturing a photodetector;

FIG. 11F is an explanatory view for the method for manufacturing a photodetector;

FIG. 11G is an explanatory view for the method for manufacturing a photodetector;

FIG. 11H is an explanatory view for the method for manufacturing a photodetector;

FIG. 11I is an explanatory view for the method for manufacturing a photodetector;

FIG. 12A is an explanatory view for the method for manufacturing a photodetector;

FIG. 12B is an explanatory view for the method for manufacturing a photodetector;

FIG. 12C is an explanatory view for the method for manufacturing a photodetector;

FIG. 12D is an explanatory view for the method for manufacturing a photodetector;

FIG. 12E is an explanatory view for the method for manufacturing a photodetector;

FIG. 12F is an explanatory view for the method for manufacturing a photodetector;

FIG. 12G is an explanatory view for the method for manufacturing a photodetector;

FIG. 12H is an explanatory view for the method for manufacturing a photodetector;

FIG. 13 is an explanatory view for the method for manufacturing a photodetector;

FIG. 14A is an explanatory view for a method for manufacturing a photodetector;

FIG. 14B is an explanatory view for the method for manufacturing a photodetector;

FIG. 14C is an explanatory view for the method for manufacturing a photodetector;

FIG. 15A is an explanatory view for a method for manufacturing a photodetector;

FIG. 15B is an explanatory view for the method for manufacturing a photodetector;

FIG. 15C is an explanatory view for the method for manufacturing a photodetector;

FIG. 15D is an explanatory view for the method for manufacturing a photodetector;

FIG. 15E is an explanatory view for the method for manufacturing a photodetector;

FIG. 15F is an explanatory view for the method for manufacturing a photodetector;

FIG. 15G is an explanatory view for the method for manufacturing a photodetector;

FIG. 15H is an explanatory view for the method for manufacturing a photodetector;

FIG. 15I is an explanatory view for the method for manufacturing a photodetector;

FIG. 16A is an explanatory view for the method for manufacturing a photodetector;

FIG. 16B is an explanatory view for the method for manufacturing a photodetector;

FIG. 16C is an explanatory view for the method for manufacturing a photodetector;

FIG. 16D is an explanatory view for the method for manufacturing a photodetector;

FIG. 16E is an explanatory view for the method for manufacturing a photodetector;

FIG. 16F is an explanatory view for the method for manufacturing a photodetector;

FIG. 16G is an explanatory view for the method for manufacturing a photodetector;

FIG. 16H is an explanatory view for the method for manufacturing a photodetector;

FIG. 17A is an explanatory view for a method for manufacturing a photodetector;

FIG. 17B is an explanatory view for the method for manufacturing a photodetector; and

FIG. 18 is a view of the photodetector.

### DETAILED DESCRIPTION

According to an embodiment, a photodetector includes a photo detection layer, a plurality of light conversion members, and a first member. The photo detection layer includes, on a light incident surface on which light is incident, a plurality of pixel regions and a surrounding region. The plurality of pixel regions each holds a photo detection element configured to detect the light. The surrounding region is a region other than the pixel regions on the light incident surface. The plurality of light conversion members is arranged so as to oppose the pixel regions in the photo detection layer and converts radiation to the light. Each of the light conversion members includes a bottom surface opposing the pixel region in the photo detection layer, a top surface opposing the bottom surface, and a lateral surface connecting the bottom surface and the top surface. The first member is disposed on at least a portion of the surrounding region on the light incident surface and covers a portion of the lateral surface of the light conversion member.

Various embodiments will be described in detail below with reference to the accompanying drawings. In the present description, similar members or sections indicating similar functions are denoted with similar reference numerals and the description thereof will be omitted in some cases.

### First Embodiment

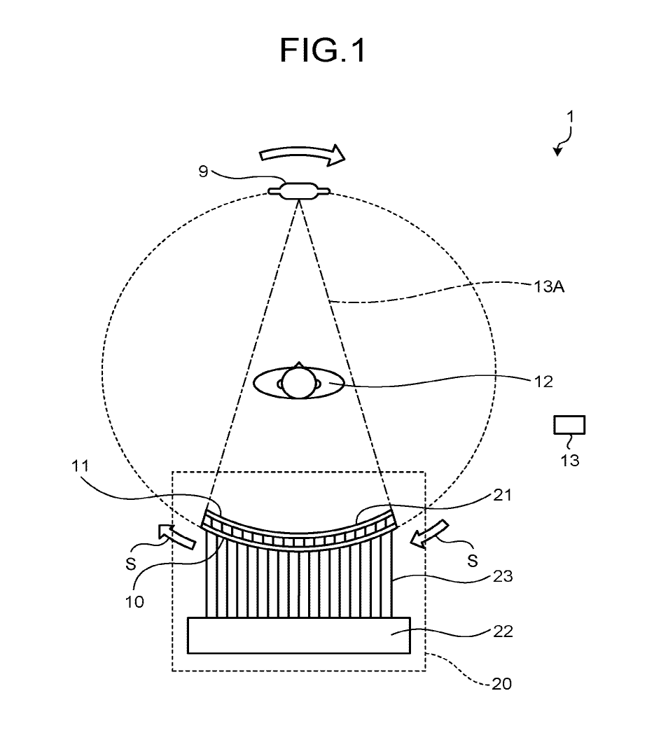

FIG. 1 is a schematic view illustrating an exemplary inspection device 1 according to the embodiment.

The inspection device 1 includes a light source 9, a detection unit 20, and a driving unit 13. The light source 9 and the driving unit 13 may be electrically connected to the detection unit 20.

The light source 9 and the detection unit 20 are arranged so as to oppose each other with an interval. In addition, the light source 9 and the detection unit 20 are disposed rotatably about a subject 12 while maintaining the aforementioned opposing state of arrangement.

The light source 9 radiates a radiation 13A such as an X-ray toward the opposing detection unit 20. The radiation 13A radiated from the light source 9 passes through the subject 12 on a trestle (not illustrated) and then enters the photodetector 10 disposed in the detection unit 20.

The detection unit 20 includes the plurality of photodetectors 10 and a signal processing circuit 22. The photodetector 10 is a device that detects light. The photodetectors 10 and the signal processing circuit 22 are electrically connected to each other. In the embodiment, the plurality of photodetectors 10 disposed in the detection unit 20 is arrayed along a predetermined rotation direction (a direction indicated by arrows S in FIG. 1).

Each of the photodetector 10 receives, via a collimator 21, the radiation 13A as light, which has been radiated from the light source 9 and then passed through the subject 12. The collimator 21 is installed on the side of a light incident surface 11 of the photodetector 10 and refracts the radiation 13A such that the radiation 13A enters the photodetector 10 in parallel thereto.

The photodetector 10 detects light. The photodetector 10 outputs an electrical signal in accordance with the detected light to the signal processing circuit 22 via a signal line 23. The signal processing circuit 22 controls the entire inspection device 1. The signal processing circuit 22 acquires the electrical signal from the photodetector 10.

In the embodiment, the signal processing circuit 22 calculates, from a current value of the acquired electrical signal, the energy and the strength of the radiation that has entered each of the photodetectors 10. Thereafter, the signal processing circuit 22 generates a radiation image of the subject 12 from the energy and the strength of the radiation entering each of the photodetectors 10.

The driving unit 13 rotates the light source 9 and the detection unit 20 about the subject 12 positioned between the light source 9 and the photodetectors 10 in the rotation direction (the direction indicated by the arrows S in FIG. 1) while maintaining the opposing state of the light source 9 and the detection unit 20. As a result, the inspection device 1 can generate a cross-sectional image of the subject 12. The driving unit 13 may rotate the photodetectors 10 in the detection unit 20 and the light source 9 while maintaining the opposing state thereof.

The subject 12 is not limited to a human body. The subject 12 may be an animal or a plant, or alternatively, may be a nonliving thing such as an article. Accordingly, the inspection device 1 can be applied as various types of inspection devices not only for tomographic images of a human body, an animal, and a plant, but also, for example, for the observation of the inside of an article by seeing therethrough, such as a security device.

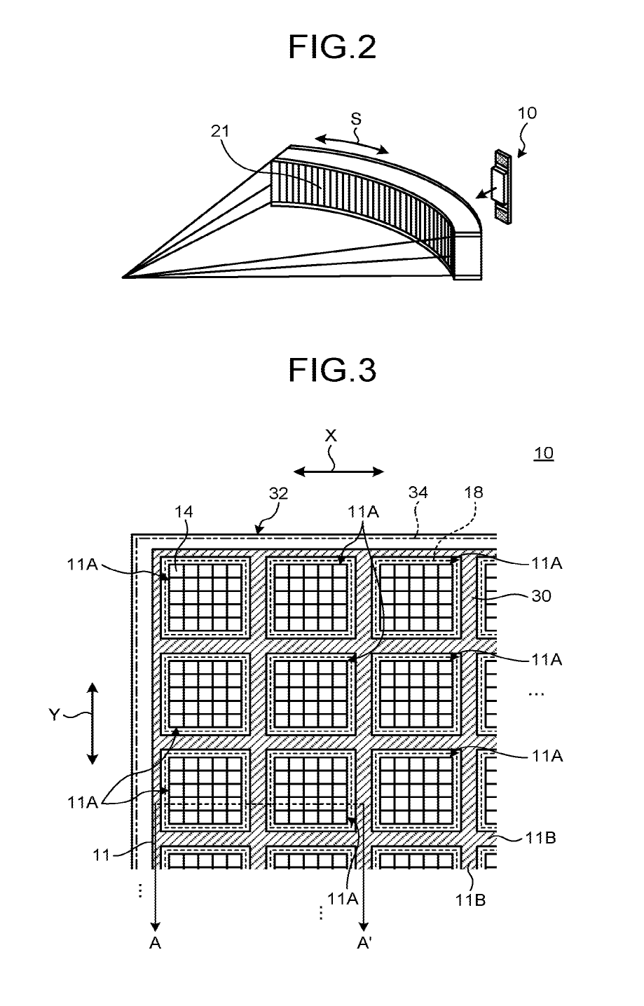

FIG. 2 is a view illustrating an array state of the photodetector 10 equipped in the inspection device 1. The plurality of photodetectors 10 is arrayed substantially in a circular arc shape along the rotation direction (the directions indicated by the arrows S in FIG. 1 and FIG. 2). The collimator 21 is disposed on a light incident side of the photodetector 10.

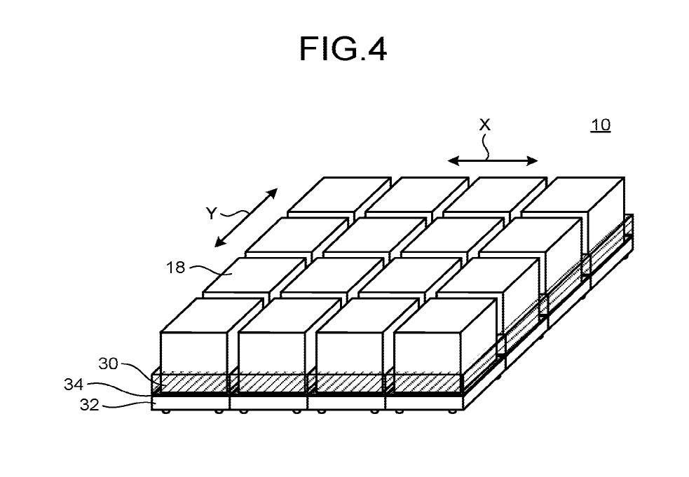

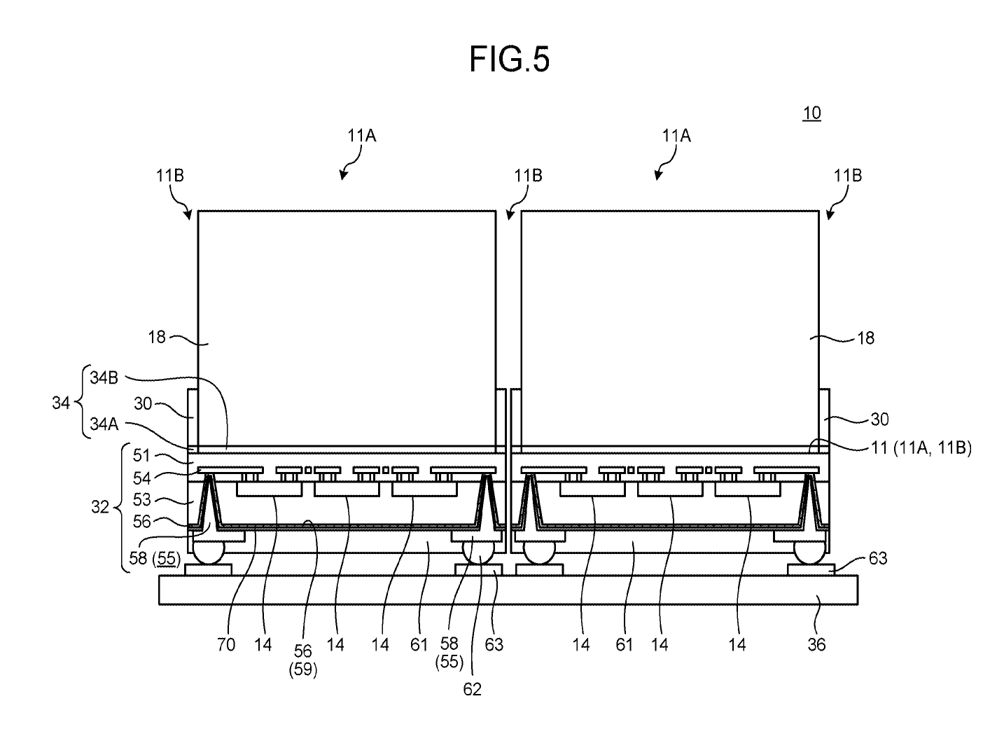

FIG. 3 is a plan view illustrating an example of the photodetector 10. FIG. 4 is a perspective view illustrating an example of the photodetector 10. FIG. 5 is a cross-sectional view taken along line A-A′ in FIG. 3.

As illustrated in FIG. 5, the photodetector 10 includes a photo detection layer 32, an adhesive layer 34, light conversion members 18, and a first member 30.

The light conversion members 18 convert the radiation into light (photon) having a longer wavelength than that of the radiation. The light converted at the light conversion members 18 is emitted to the photo detection layer 32. This means that the light conversion members 18 are arranged on a light incident surface side of the photo detection layer 32. The light conversion member 18 includes a top surface, a bottom surface opposing this top surface, and a lateral surface connecting the top surface and the bottom surface. The bottom surface opposes a pixel region 11A in the photo detection layer 32 described later. For example, in a case where the light conversion member 18 has a quadrangular prism shape, the light conversion member 18 has four lateral surfaces.

The light conversion member 18 is composed of a scintillator. The scintillator emits fluorescence (scintillation light) when the radiation such as the X-ray enters the scintillator. In the embodiment, the fluorescence (scintillation light) emitted by the light conversion member 18 is simply referred to as light in the description. The constituent material of the scintillator is selected as appropriate depending on an object to which the photodetector 10 is applied. For example, the scintillator is made of Lu₂SiO₅:(Ce), LaBr₃:(Ce), YAP (yttrium aluminum perovskite):Ce, or Lu(Y)AP:Ce, but not limited thereto.

The photo detection layer 32 detects the light converted at the light conversion members 18. The photo detection layer 32 is a silicon photo multiplier (SiPM) in which a plurality of avalanche photo diodes (APDs) is arrayed as the photo detection elements 14. The APD is a publicly known avalanche photo diode. In the embodiment, the photo detection element 14 is driven in a Geiger mode.

As illustrated in FIG. 3, the plurality of photo detection elements 14 is arrayed in a matrix form (refer to a direction indicated by an arrow X and a direction indicated by an arrow Y in FIG. 3). The photo detection layer 32 has a configuration in which the plurality of photo detection elements 14 is set as one pixel (pixel region 11A) and the plurality of pixel regions 11A is arrayed in a matrix form.

In detail, the photo detection layer 32 includes, on the light incident surface 11 on which the light is incident, the pixel regions 11A, each of which holds the plurality of photo detection elements 14 configured to detect the light, and a surrounding region 11B corresponding to a section other than the pixel regions 11A on the light incident surface 11.

FIG. 3 has illustrated a case where each of the pixel regions 11A is configured so as to have 25 (5×5) photo detection elements 14 in array. However, the number of the photo detection elements 14 constituting each of the pixel regions 11A is merely an example and not limited to 25.

As illustrated in FIG. 5, the light conversion members 18 are arranged so as to oppose the pixel regions 11A. In the embodiment, the light conversion members 18 are arranged on the side of the light incident surface 11 of the photo detection layer 32.

The photodetector 10 has a layered structure in which the photo detection layer 32, the adhesive layer 34, and the light conversion members 18 along with the first member 30 are layered in this order. The light conversion members 18 and the first member 30 are adhered to the photo detection layer 32 through the adhesive layer 34.

In the example illustrated in FIG. 5, the adhesive layer 34 is composed of a second adhesive layer 34B adhering the light conversion members 18 and the photo detection layer 32 to each other and a first adhesive layer 34A adhering the photo detection layer 32 and the first member 30 to each other. The adhesive layer 34 may be composed of one layer, or alternatively, may be composed of a plurality of layers. For example, the adhesive layer 34 may have a layered structure in which the first adhesive layer 34A and the second adhesive layer 34B are layered.

The adhesive layer 34 has a transmission property allowing the light emitted from the light conversion members 18 to pass through. A layer thickness of the adhesive layer 34 is not limited and, for example, ranges from several micrometers to several hundred micrometers.

The photo detection layer 32 has a layered structure in which a silicon oxide layer 51, a second silicon layer 53, an insulation film 56, and the like are layered in this order from the side of the light incident surface 11.

The silicon oxide layer 51 holds a common wire 54 therein. For example, the main component of the silicon oxide layer 51 is silicon dioxide (SiO₂). The common wire 54 is provided extending along the light incident surface 11 of the photo detection layer 32 in a flat surface shape and serves as a mesh-shaped metal wire arranged so as to be accommodated within the pixel region 11A. The common wire 54 is made of, for example, aluminum or copper.

On a region of the second silicon layer 53 in contact with the silicon oxide layer 51, the plurality of photo detection elements 14 is arrayed along the light incident surface 11 for each of the pixel region 11A.

The photo detection element 14 is an APD formed as a PN-type diode obtained by doping a P-type silicon layer with boron. The photo detection element 14 electrically connects, through the avalanche breakdown, the side of the silicon oxide layer 51 (anode) with the side of the second silicon layer 53 (cathode) in the photo detection element 14 in a reverse bias direction. Each of the photo detection elements 14 within the pixel region 11A is connected to the common wire 54 via a lead wire inserted into a contact hole formed toward the common wire 54 from the anode side of the photo detection element 14. For example, the photo detection elements 14 are formed at intervals of 25 μm with one another.

In addition, each of the photo detection elements 14 has a serial resistance (not illustrated). For example, this serial resistance is formed by a polysilicon layer. The common wire 54 is not limited to serving as the mesh-shaped metal wire. The common wire 54 is at least required to have a light transmittance at a level enough for the photo detection element 14 to be able to detect the incident light from the light conversion members 18 and a shape allowing the photo detection elements 14 within the same pixel region 11A to electrically connect with each other via the lead wire.

The second silicon layer 53 is a layer formed of N-type silicon. The second silicon layer 53 electrically connects each of the photo detection elements 14 within the pixel region 11A with a common electrode 59 described later.

The insulation film 56 is a layer shielding a surface of the second silicon layer 53 on an opposite side of the silicon oxide layer 51. The insulation film 56 is formed by an insulating member. For example, the insulation film 56 is formed of silicon dioxide (SiO₂). A solder mask 61 is disposed on a surface of the insulation film 56 on an opposite side of the second silicon layer 53 with a seed layer 70 interposed therebetween.

In addition, a recessed portion 55 is formed in the photo detection layer 32 so as to pass through the second silicon layer 53 from the side of the insulation film 56 along a layered direction of the second silicon layer 53 and the silicon oxide layer 51 until a position where the common wire 54 within the silicon oxide layer 51 is reached. An inner side of the recessed portion 55 is filled with a through electrode 58 with the insulation film 56 interposed therebetween. The through electrode 58 and the common wire 54 are electrically connected with each other.

The common electrode 59 is disposed on a portion of a region of the insulation film 56 extending toward the center of the pixel region 11A from the recessed portion 55.

In the example illustrated in FIG. 5, the photodetector 10 is mounted on a mounted substrate 36. The photodetector 10 is mounted on the mounted substrate 36 with the through electrode 58, a bump 62, and an electrode 63 interposed therebetween.

When the photodetector 10 configured as described above is irradiated with the radiation 13A (refer to FIG. 1) from the light source 9 (refer to FIG. 1), the radiation 13A enters the light conversion members 18 of the photodetector 10. The light conversion members 18 convert the radiation 13A to light and emit the light to the photo detection layer 32.

The light emitted from the light conversion members 18 enters the photo detection elements 14 in the photo detection layer 32.

A drive voltage in reverse bias relative to a PN junction of the photo detection element 14, which is equal to or higher than an avalanche breakdown voltage, is applied between the through electrode 58 and the common electrode 59 through the control by the signal processing circuit 22 (refer to FIG. 1). When the light enters the photo detection element 14 in this state, a pulsed current flows in the photo detection element 14 in a reverse bias direction, whereby a current flows between the through electrode 58 and the common electrode 59. Thereafter, the current flowing between the through electrode 58 and the common electrode 59 is output to the signal processing circuit 22 via the signal line 23 as an electrical signal. As a result, the photodetector 10 detects the light.

In the embodiment, the photodetector 10 includes the first member 30.

The first member 30 is a member disposed on at least a partial region of the surrounding region 11B on the light incident surface 11 of the photo detection layer 32 and covering a portion of the lateral surface of the light conversion member 18.

In the embodiment, the first member 30 is disposed continuously in the surrounding region 11B so as to enclose the circumference of the plurality of pixel regions 11A (refer to FIG. 3 to FIG. 5).

The shape of the first member 30 is not limited as long as the first member 30 protrudes from the light incident surface 11 of the photo detection layer 32 toward an opposite side of the light incident surface 11 so as to cover a portion of each of the light conversion members 18. It is preferable that the surfaces of the first member 30 opposing the light conversion members 18 are formed in a shape in accordance with the light conversion members 18 (refer to FIG. 3).

The length of the first member 30 in the layered direction of the light conversion member 18 and the photo detection layer 32 is at least required to be as much length as necessary to protrude from the light incident surface 11 toward the opposite side of the light incident surface 11.

However, it is preferable that the length of the first member 30 in the aforementioned layered direction be smaller than the length of the light conversion member 18 adjacent to that first member 30 in the aforementioned layered direction.

It is preferable that the width of the first member 30 in a direction along the light incident surface 11 be smaller than the interval between the adjacent pixel regions 11A. In addition, a minimum value of the width of the first member 30 in the direction along the light incident surface 11 is at least required to be a width that can realize as much strength as necessary to prevent damage to the photo detection layer 32 and a crystal defect therein from occurring during a manufacturing process for the photodetector 10.

The material of the first member 30 is not limited. It is preferable for the first member 30 to have light reflectivity. In detail, it is preferable that at least a section of the first member 30 covering the light conversion members 18 be formed of a light reflective material. For example, it is preferable that at least a section of the first member 30 opposing the lateral surfaces of the light conversion members 18 be formed of a light reflective material and a portion thereof other than this section be formed of a light transmissive material. The lateral surfaces of the light conversion member 18 are surfaces of the light conversion members 18 intersected by an imaginary straight line perpendicular to the layered direction of the light conversion members 18 and the photo detection layer 32.

The light reflectivity according to the embodiment at least represents a property of reflecting the light detected by the photo detection element 14. The light transmission property according to the embodiment at least represents a property of transmitting the light detected by the photo detection element 14.

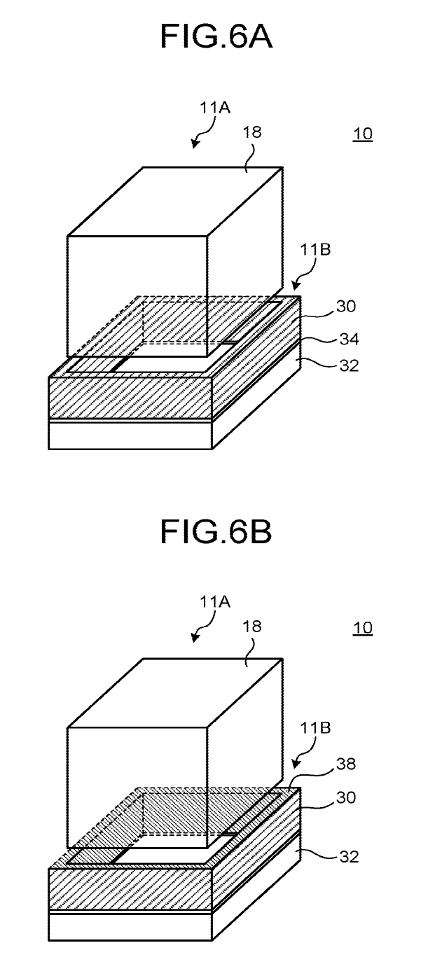

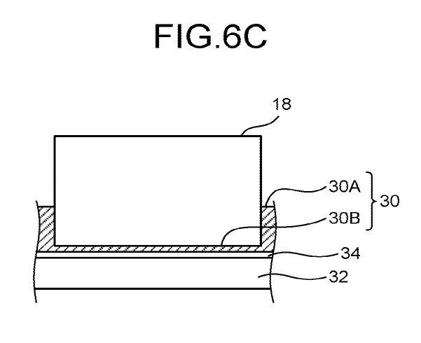

FIG. 6A to FIG. 6C are enlarged schematic views, each illustrating a section corresponding to one pixel region 11A in the photodetector 10. For the purpose of the description, each of FIG. 6A to FIG. 6C illustrates a state where the light conversion members 18 are not bonded to the side of the photo detection layer 32. Actually, however, the light conversion members 18 are arranged so as to oppose the pixel regions 11A in the photo detection layer 32 and be bonded to the photo detection layer 32 with the adhesive layer 34 interposed therebetween. Accordingly, the light conversion members 18 are put into a state where at least a portion of an outer circumferential surface thereof in a direction intersecting the aforementioned layered direction is supported by the first member 30.

FIG. 6A is an enlarged schematic view illustrating a portion of the first member 30.

As described above, it is preferable that at least a section of the first member 30 opposing the lateral surfaces of the light conversion members 18 be formed of a light reflective material and a portion thereof other than this section be formed of a light transmissive material. With this configuration, the enhancement of the sensitivity of the photo detection element 14 can be achieved.

The first member 30 may be entirely formed of a light transmissive material. From the viewpoint of the enhancement of the sensitivity, however, it is preferable that at least a section of the first member 30 opposing the lateral surface of the light conversion member 18 be formed of a light reflective material and a portion thereof other than this section be formed of a light transmissive material. A publicly known glass material or the like can be used as the light transmissive material.

When the first member 30 has the reflectivity, the light converted at the light conversion members 18 is reflected by the first member 30 and then emitted to the photo detection layer 32 efficiently. As a consequence, the enhancement of the light detection ability of the photo detection element 14 can be achieved. In addition, compared to a case where a reflective member having the reflectivity is separately disposed in the photodetector 10, an uncomplicated configuration and simplified manufacturing can be achieved for the photodetector 10.

When the first member 30 is configured to have the reflectivity, the first member 30 is simply made of a material having a property of reflecting light in a sensitivity wavelength range of the photo detection element 14. For example, the first member 30 can be made of a material obtained by mixing fine powder of TiO₂, BaSO₄, Ag, or the like to binder resin.

The first member 30 may be configured to be disposed with a reflection layer having the aforementioned reflectivity on the surfaces thereof opposing the light conversion members 18. Specifically, a section of the first member 30 on the side of the collimator 21 (refer to FIG. 1) may have the light reflectivity. FIG. 6B is a schematic view illustrating a configuration with a reflection layer 38 provided on the surfaces of the first member 30 opposing the light conversion members 18.

When the first member 30 includes the reflection layer 38 on the surfaces thereof opposing the light conversion members 18, the light converted at the light conversion members 18 is reflected by the reflection layer 38. As a consequence, the enhancement of the light detection ability of the photo detection element 14 can be achieved. The reflection layer 38 is simply made of a material having at least a property of reflecting light in a sensitivity wavelength range of the photo detection element 14. For example, the reflection layer 38 can be made of a material obtained by mixing fine powder of TiO₂, BaSO₄, Ag, or the like to binder resin.

The reflection layer 38 may be disposed so as to cover at least a section of the light conversion members 18 not disposed in the first member 30.

As described thus far, the photodetector 10 according to the embodiment includes the first member 30.

Here, conventionally, there is a case where, in the manufacturing process for the photodetector 10, damage to the photo detection element 14 or a crystal defect therein occurs when a supporting substrate used during the manufacturing process is removed from the photo detection layer 32 including the photo detection element 14. Meanwhile, when the photodetector 10 is configured to be provided with the supporting substrate without removing the supporting substrate, there has been a case where crosstalk occurs between the adjacent pixel regions 11A. For this reason, in the past, the detection accuracy of the photo detection element 14 has been deteriorated in some cases.

On the other hand, the photodetector 10 according to the embodiment includes the first member 30. The first member 30 is a member disposed on at least a partial region of the surrounding region 11B on the light incident surface 11 of the photo detection layer 32 and protruding toward the opposite side of the light incident surface 11.

Accordingly, when the photodetector 10 is manufactured, even in a case where the supporting substrate is bonded for the purpose of reinforcing and protecting the photo detection layer 32 during manufacturing, the supporting substrate is bonded to the side of the photo detection layer 32 with the first member 30 interposed therebetween and, in this state, the photo detection layer 32 is subjected to processing. As a result, the occurrence of damage to the photo detection element 14 and a crystal defect therein can be suppressed while the supporting substrate is removed. In addition, because it is not necessary to configure the photodetector 10 as including the supporting substrate, the occurrence of crosstalk can be suppressed.

Consequently, the photodetector 10 according to the embodiment can suppress the deterioration of the detection accuracy of the photo detection element 14.

Meanwhile, the first member 30 is disposed on at least a portion of the surrounding region 11B corresponding to a section other than the pixel region 11A on the light incident surface 11 of the photo detection layer 32. Besides, the first member 30 has a shape protruding from the light incident surface 11 toward the opposite side of the light incident surface 11. Accordingly, when the light conversion members 18 are arranged during the manufacturing process for the photodetector 10, each of the light conversion members 18 can be arranged so as to oppose the pixel region 11A by using the first member 30 as a positioning member.

As a result, in the embodiment, the light conversion members 18 can be accurately arranged so as to oppose the pixel region 11A. Consequently, the photodetector 10 according to the embodiment can suppress the deterioration of the detection accuracy of the photo detection element 14.

Additionally, in the embodiment, the first member 30 is disposed continuously in the surrounding region 11B so as to enclose the plurality of pixel regions 11A (refer to FIG. 3). As a result, the effect of the first member 30 for reinforcing the photo detection layer 32 can be enhanced while the photodetector 10 is manufactured.

Furthermore, the first member 30 is disposed continuously in the surrounding region 11B so as to enclose each of the plurality of pixel regions 11A and thus, the light conversion members 18 can be accurately arranged so as to oppose each of the pixel regions 11A while the photodetector 10 is manufactured.

Meanwhile, in the embodiment, the first member 30 is disposed on the whole region of the surrounding region 11B other than the pixel region 11A on the light incident surface 11 of the photo detection layer 32. As a result, the light conversion members 18 can be accurately and easily arranged so as to oppose each of the pixel regions 11A while the photodetector 10 is manufactured. Consequently, the photodetector 10 according to the embodiment can further suppress the deterioration of the detection accuracy of the photo detection element 14.

In addition, in the embodiment, the surfaces of the first member 30 opposing the light conversion members 18 are formed in a shape in accordance with the light conversion members 18. Accordingly, when the light conversion members 18 are arranged during the manufacturing process for the photodetector 10, each of the light conversion members 18 can be easily and accurately arranged so as to oppose the pixel region 11A by using the first member 30 as a positioning member.

Furthermore, the surfaces of the first member 30 opposing the light conversion members 18 are formed in a shape in accordance with the light conversion member 18 and thus, bonding areas of the first members 30 to the side of the photo detection layer 32 can be made larger. As a result, the effect of the first member 30 for reinforcing the photo detection layer 32 can be further enhanced while the photodetector 10 is manufactured.

Meanwhile, in the embodiment, the length of the first member 30 in the aforementioned layered direction is smaller than the length of the light conversion member 18 adjacent to that first member 30 in the aforementioned layered direction. When the length of the first member 30 in the aforementioned layering direction is smaller than the length of that light conversion member 18 in the aforementioned layered direction, the first member 30 can be used as a positioning member. While the photodetector 10 is manufactured, the light conversion members 18 can be arranged so as to oppose the pixel region 11A more easily and accurately.

The first member 30 may be formed of a light transmissive material. Alternatively, the first member 30 may include a light transmissive material and a reflective material for covering the light conversion members 18 made of this light transmissive material.

Alternatively, a portion of the first member 30 may be disposed between the pixel region 11A in the photo detection layer 32 and the light conversion member 18.

FIG. 6C is a schematic view illustrating another mode of the first member 30. As illustrated in FIG. 6C, the first member 30 may include a first portion 30A covering a portion of the lateral surfaces of the light conversion member 18 and a second portion 30B provided between the photo detection layer 32 and the light conversion member 18. The thickness of the second portion 30B is thinner than the thickness of the first portion 30A. The thickness of the first portion 30A and the thickness of the second portion 30B represent respective thicknesses of the first portion 30A and the second portion 30B in the layered direction of the silicon oxide layer 51, the second silicon layer 53, and the insulation film 56.

For example, the thickness of the second portion 30B out of the first member 30 can be set to 30 μm or smaller. Meanwhile, the thickness of the first portion 30A can be set to thicker than 30 μm.

When a portion of the first member 30 is disposed between the pixel region 11A in the photo detection layer 32 and the light conversion member 18, this portion is configured to have the light transmission property. Specifically, the second portion 30B is configured to have the light transmission property.

First Modification

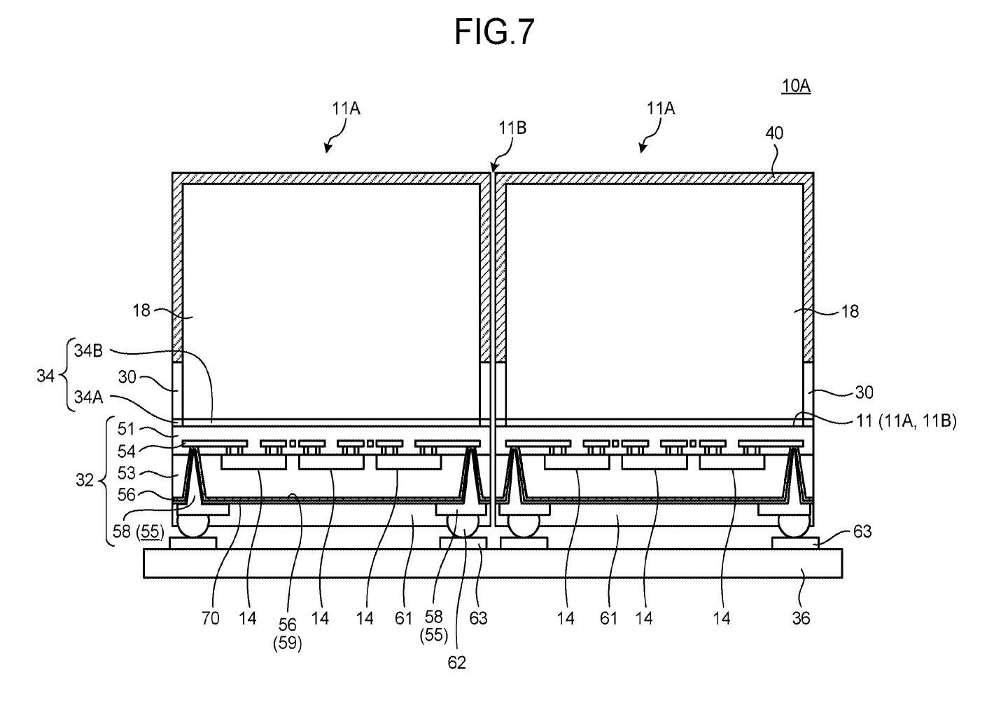

The photodetector 10 described in the first embodiment may be configured to further include reflective members 40. FIG. 7 is an explanatory view of a photodetector 10A provided with the reflective members 40. The photodetector 10A is configured to further include the reflective members 40 in addition to the photodetector 10 described in the first embodiment. The reflective member 40 covers a section of the lateral surfaces of the light conversion member 18 other than a section thereof opposing the first member 30. The reflective member 40 also covers a top surface of the light conversion member 18 opposing the collimator 21.

The reflective member 40 transmits the radiation 13A entering the light conversion member 18 (refer to FIG. 1) while reflecting the light converted at the light conversion member 18. The reflective member 40 can be made of a material having such a property.

The reflective members 40 are arranged in a manner to separate the light conversion members 18 into regions corresponding to the pixel regions 11A. In addition, an end portion of the reflective member 40 on the side of the photo detection layer 32 is bonded to the first member 30. The reflective member 40 covering a certain light conversion member 18 and the reflective member 40 covering another light conversion member 18 disposed adjacent to the certain light conversion member 18 may not be separated so as to be continuously disposed. In other words, one reflective member 40 may cover the plurality of light conversion members 18.

The plurality of photo detection layers 32 may be formed so as to be separated from one another, or alternatively, may be formed so as to continue to one another instead of being separated. When the plurality of photo detection layers 32 is separated from one another, the reflective member 40 may be formed between the two adjacent photo detection layers 32. As an example, FIG. 7 illustrates a case where the reflective members 40 and the first members 30 are structured so as to be separated within the surrounding region 11B. However, it is only required to separate the pixel regions 11A from each other and thus, at least portions of the surrounding regions 11B may be integrated to each other through a region corresponding to a space between the pixel regions 11A.

Because the photodetector 10A includes the reflective member 40, the enhancement of the light detection ability of the photo detection element 14 can be achieved in addition to the effect in the first embodiment.

Second Modification

As an example, the aforementioned embodiment has described a case where the first members 30 are disposed continuously in the surrounding region 11B so as to enclose the circumference of each of the plurality of pixel regions 11A. However, the first member 30 is only required to be disposed on at least a partial region of the surrounding region 11B on the light incident surface 11 of the photo detection layer 32.

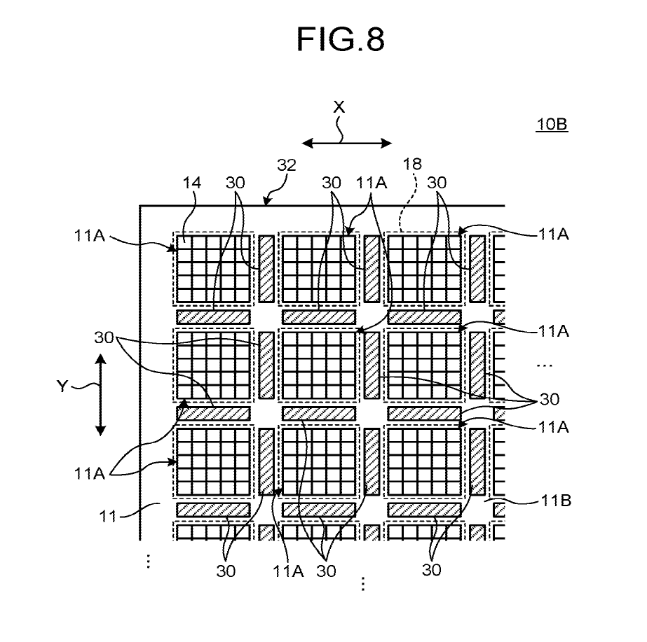

FIG. 8 is a view illustrating a photodetector 10B according to the modification. As illustrated in FIG. 8, a mode may be employed in which the first members 30 are discontinuously disposed within the surrounding region 11B. The example illustrated in FIG. 8 indicates a mode where the first members 30 are discontinuously disposed in regions between the adjacent pixel regions 11A within the surrounding region 11B along a surface direction. The photodetector 10B is similar to the photodetector 10 illustrated in FIG. 1 except for having a different arrangement of the first member 30 within the surrounding region 11B.

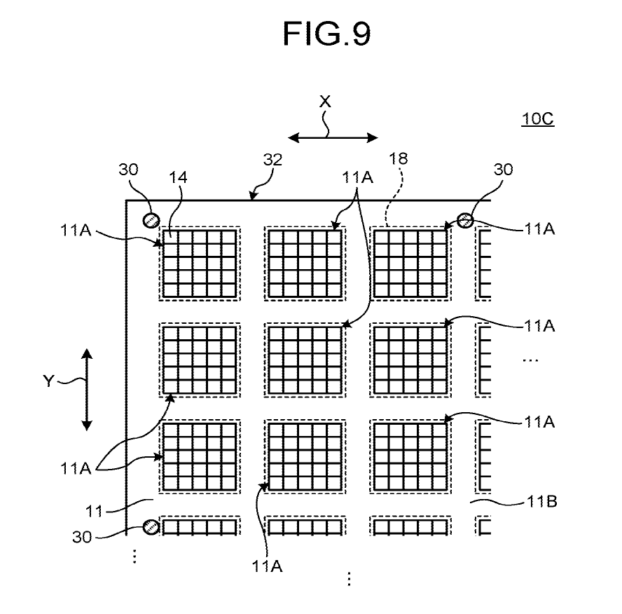

FIG. 9 is a view illustrating a photodetector 10C according to the modification. As illustrated in FIG. 9, the first members 30 may be discontinuously disposed in regions other than spaces between the adjacent pixel regions 11A within the surrounding regions 11B. The photodetector 10C is similar to the photodetector 10 illustrated in FIG. 1 except for having a different arrangement of the first member 30 within the surrounding region 11B.

The first members 30 may be formed so as to be discontinuously disposed in both of the regions between the adjacent pixel regions 11A and the regions other than the regions between the adjacent pixel regions 11A in the surrounding regions 11B on the light incident surface 11 (the illustration is omitted).

Each of FIG. 8 and FIG. 9 has indicated a case where a cross-section of the first member 30 parallel to the light incident surface 11 has a rectangular shape. The cross-section of the first member 30 parallel to the light incident surface 11 is not limited to the rectangular shape and can be formed into an arbitrary shape such as a belt shape, an oval shape, or a circular shape. In addition, one first member 30 may be formed in the surrounding regions 11B between the plurality of pixel regions 11A arranged in a line and another plurality of pixel regions 11A arranged in another line. This first member 30 may be disposed in a belt shape along the plurality of pixel regions 11A arranged in a line.

Furthermore, when the first members 30 are discontinuously disposed, the first members 30 may be disposed at least on a downstream side of the pixel region 11A in a first direction in the surrounding region 11B on the light incident surface 11. The first direction represents a direction in which force is applied to the photo detection element 14 when the photodetector 10 is driven in a predetermined direction.

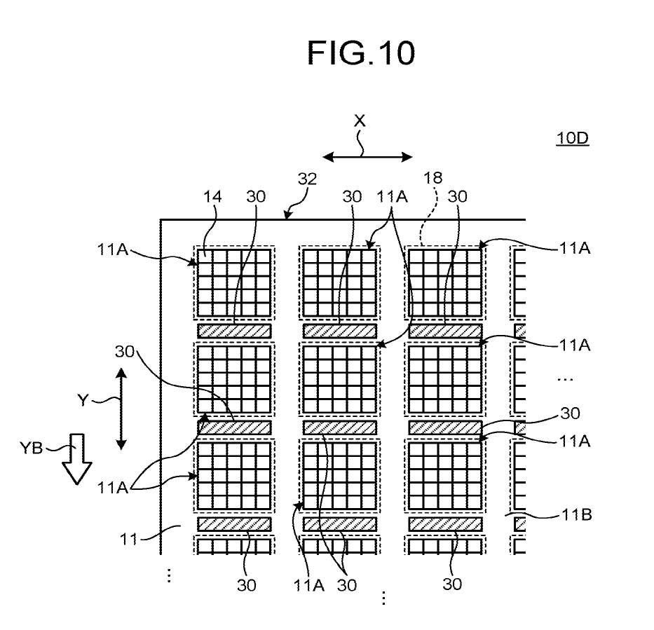

FIG. 10 is a schematic view of a photodetector 10D. The photodetector 10D has a configuration in which the first member 30 is disposed on the downstream side of each of the plurality of pixel regions 11A in the first direction (a direction indicated by an arrow YB in FIG. 10) in the surrounding region 11B. The photodetector 10D is similar to the photodetector 10 in the first embodiment except for having a different position at which the first member 30 is disposed.

The first direction (the direction indicated by the arrow YB in FIG. 10) can be adjusted as appropriate depending on a device in which the photodetector 10 is to be equipped. For example, when the photodetector 10 is equipped in the inspection device 1 illustrated in FIG. the photodetector 10 is driven to rotate in the rotation direction (the direction indicated by the arrows S in FIG. 1). In this case, centrifugal force is applied to the photodetector 10 because of the rotation in the rotation direction.

Accordingly, when the photo detection element 14 is equipped in the inspection device 1, the first direction (the direction indicated by the arrow YB in FIG. 10) is set so as to be a direction of the centrifugal force generated by this rotation in the rotation direction (the direction indicated by the arrows S in FIG. 1).

As described above, when the first member 30 is disposed at least on the downstream side of the pixel region 11A in the first direction in the surrounding region 11B on the light incident surface 11, the following effects are obtained. That is, the displacement between the position of the light conversion member 18 and the position of the pixel region 11A in the photo detection layer 32, which is caused by force applied to the photo detection element 14 due to driving, can be suppressed. As a result, in addition to the effect described above, the photodetector 10D can suppress the deterioration of the light detection ability of the photo detection layer 32.

A device in which the photodetector 10 is equipped is not limited to the inspection device 1. The photodetector 10 can be equipped in various types of devices.

### Second Embodiment

In the embodiment, a method for manufacturing the photodetector 10 described in the first embodiment will be described.

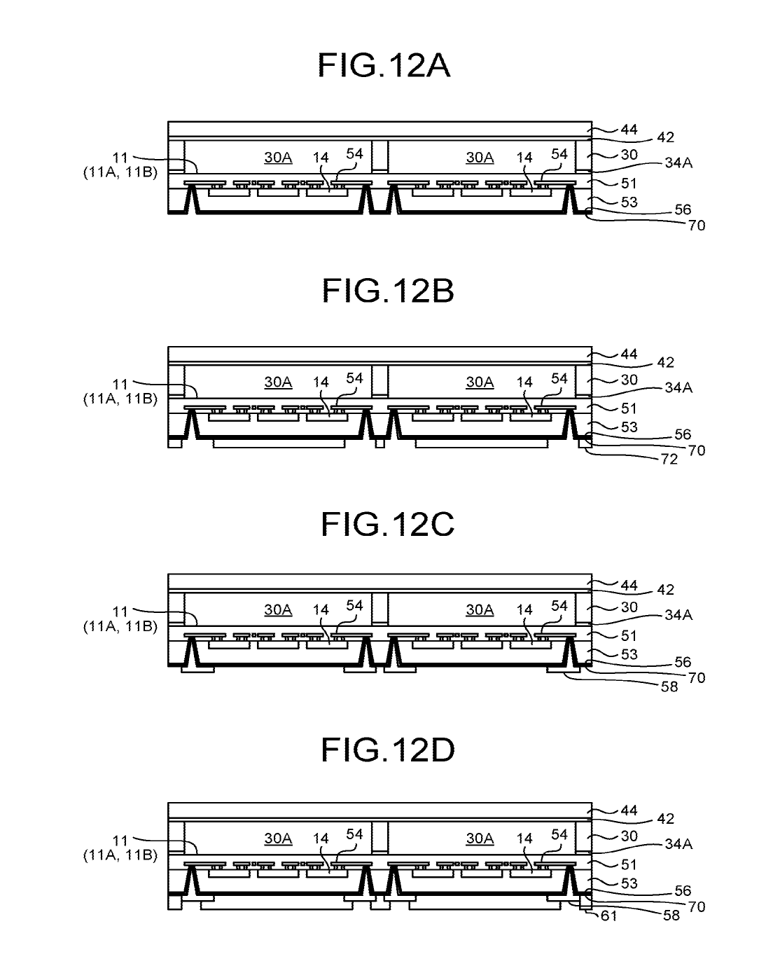

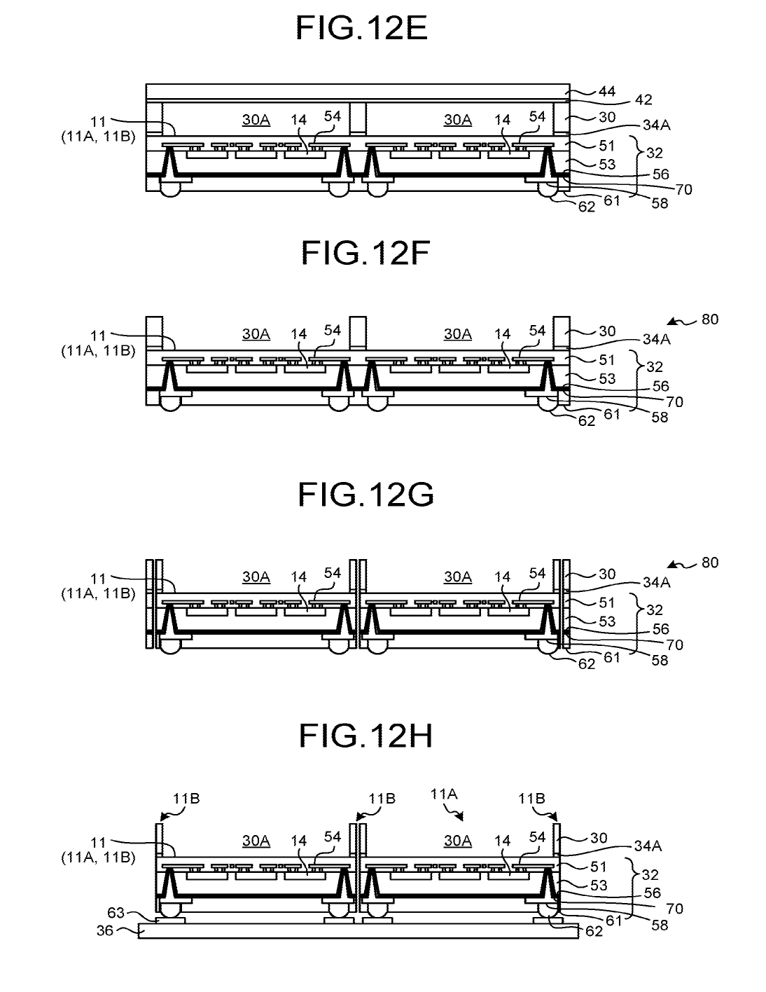

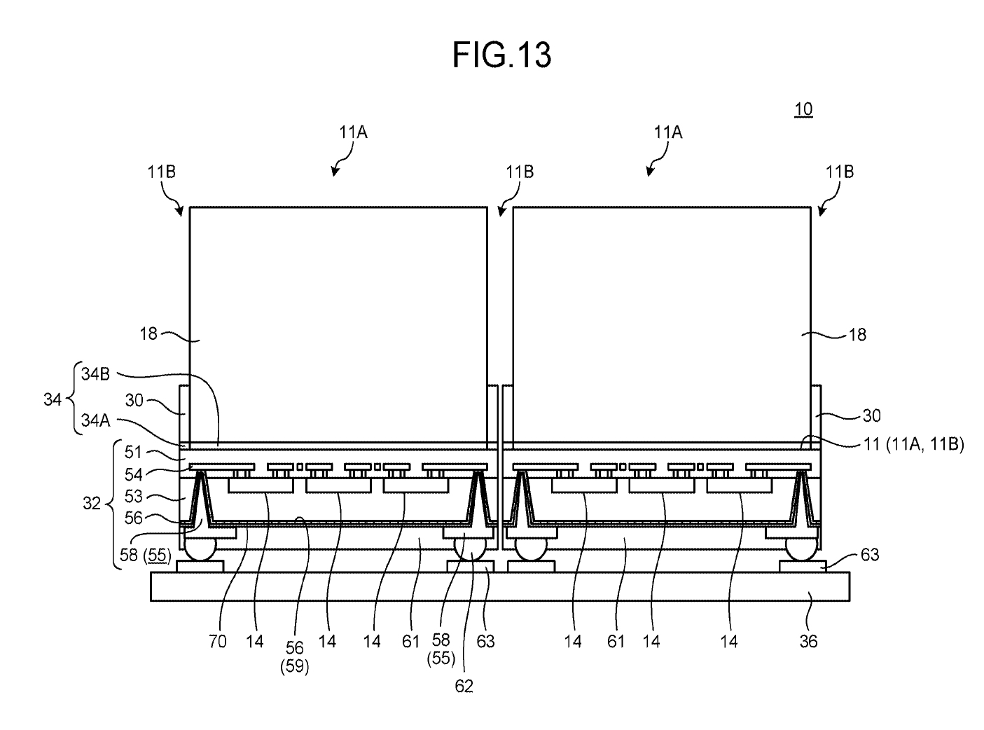

The method for manufacturing the photodetector 10 includes a first process and a second process. The first process is a process of forming a layered body 80 (refer to FIG. 12F) in which a first member 30 covering a portion of a light conversion member 18 is arranged on at least a portion of a surrounding region 11B in a photo detection layer 32. The second process is a process of arranging the light conversion member 18 such that the light conversion member 18 opposes each of pixel regions 11A in the photo detection layer 32 with the adhesive layer 34 interposed therebetween (refer to FIG. 13).

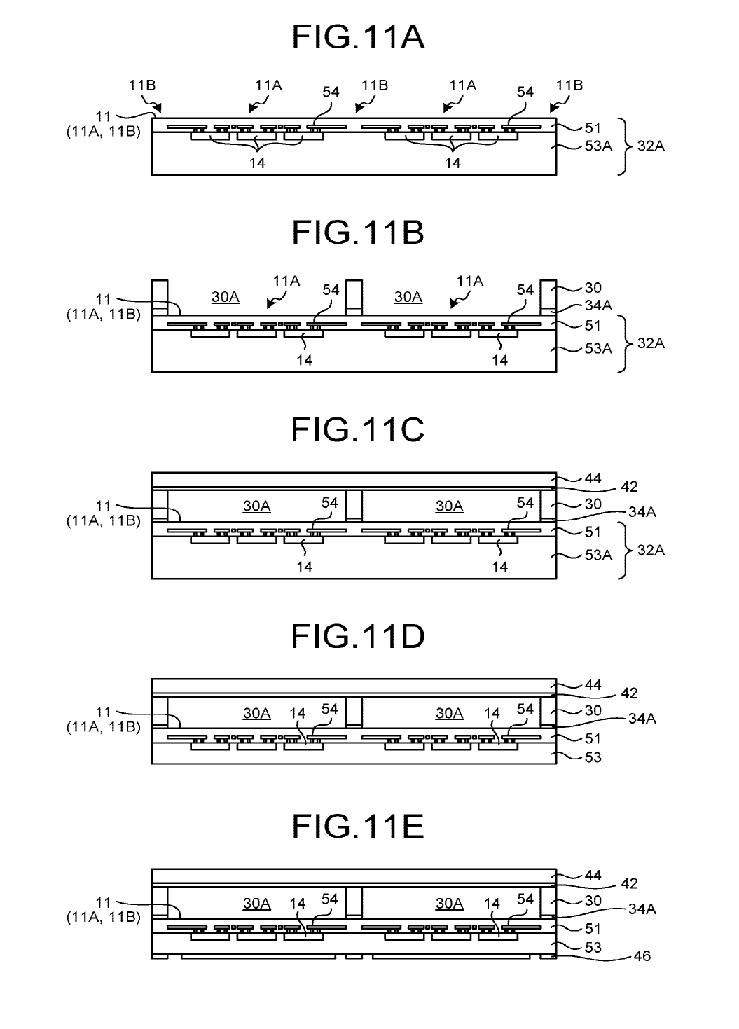

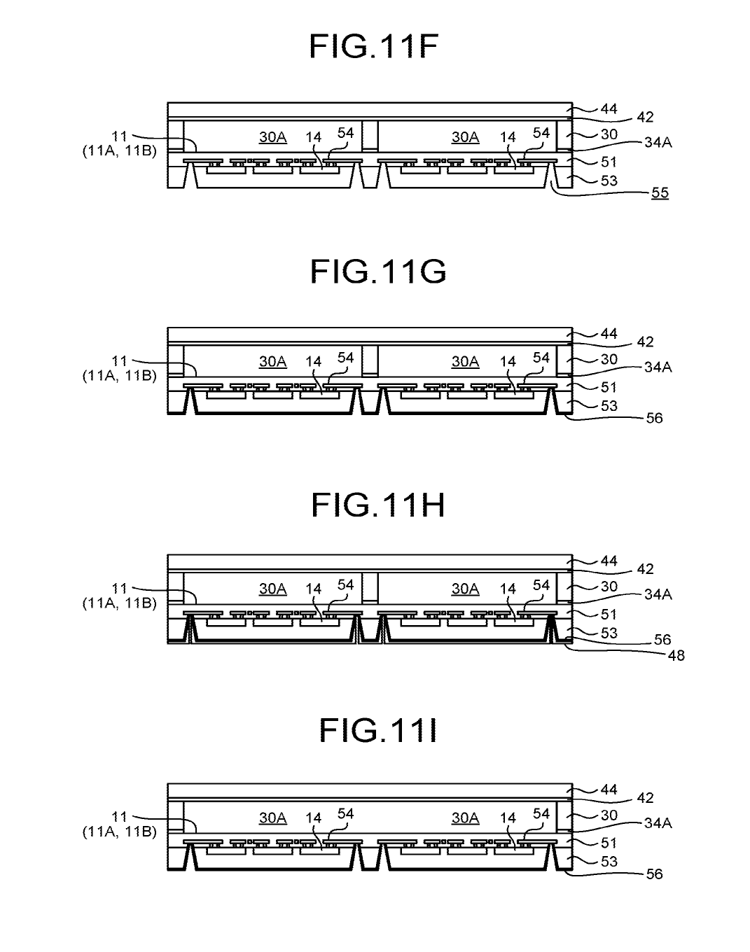

Hereinafter, the method for manufacturing the photodetector 10 will be described in detail. FIG. 11A to FIG. 11I, FIG. 12A to FIG. 12H, and FIG. 13 are explanatory views for an example of the method for manufacturing the photodetector 10.

First, multiple processes (FIG. 11A to FIG. 11I, FIG. 12A to FIG. 12H) are carried out as the first process.

As illustrated in FIG. 11A, a publicly known CMOS process is used first to carry out a process of forming, on a light incident surface 11, a first substrate 32A including the pixel region 11A and the surrounding region 11B. The first substrate 32A is a silicon substrate provided with a second silicon layer 53A, a silicon oxide layer 51, a photo detection element 14, and a common wire 54. The second silicon layer 53A is a layer composed of a second silicon layer 53 prior to being shaped into a thin film. The silicon oxide layer 51, the photo detection element 14, and the common wire 54 are similar to those in the first embodiment.

Next, as illustrated in FIG. 11B, a substrate provided with a through hole 30A at a region corresponding to each of the pixel regions 11A is prepared as the first member 30. The through hole 30A is a hole passing through this substrate in a thickness direction (same as the aforementioned layered direction).

It is preferable that a cross-sectional shape of the through hole 30A along the light incident surface 11 be the same shape as a cross-sectional shape of the pixel region 11A along the light incident surface 11. The size of the cross-section of the through hole 30A along the light incident surface 11 is at least required to be equal to or larger than the size of the cross-section of the pixel region 11A along the light incident surface 11.

The example illustrated in FIG. 11 has indicated a case where a glass substrate is prepared as the substrate. Thereafter, the through hole 30A is formed in this glass substrate using, for example, wet etching or dry etching, whereby the first member 30 is obtained. For example, an HF solution (hydrofluoric acid solution) is used for the wet etching and CF₄ (carbon tetrafluoride)-based gas is used for the dry etching.

Next, a process of arranging the first member 30 including the through hole 30A on the side of the light incident surface 11 of the first substrate 32A with a first adhesive layer 34A interposed therebetween is carried out (refer to FIG. 11B). At this time, the through hole 30A and the pixel region 11A are positioned such that the positions thereof match (alignment) and then, the first substrate 32A and the first member 30 are bonded to each other with the first adhesive layer 34A interposed therebetween.

For example, thermosetting resin or UV curable resin is used for the first adhesive layer 34A.

Next, a process of bonding a supporting substrate 44 on the side of the light incident surface 11 of the first substrate 32A with the first member 30 and an adhesive layer 42 interposed therebetween is carried out (refer to FIG. 11C).

For example, a glass substrate is used for the supporting substrate 44. The supporting substrate 44 is a plate-shaped member on which no pattern or the like is formed. This supporting substrate 44 plays a role of reinforcing and protecting the first substrate 32A, the photo detection element 14, and the like during the manufacturing process for the photodetector 10.

It is preferable that an adhesive that can be removed through UV light irradiation or the like be used for the adhesive layer 42.

Next, a process of obtaining the photo detection layer 32 by processing the first substrate 32A is carried out.

In detail, first, the second silicon layer 53A of the first substrate 32A is shaped into a thin layer until a desired thickness is obtained (refer to FIG. 11D). For example, publicly known back grinding or chemical mechanical polishing (CMP) is used for layer thinning. It is desirable that a layer thickness of the second silicon layer 53 after being shaped into a thin layer be equal to or thinner than 100 μm.

Next, a resist film 46 for forming a through electrode 58 is patterned on a rear surface of the second silicon layer 53 after being shaped into a thin layer (refer to FIG. 11E). For example, positioning and patterning of the resist film 46 are carried out in such a manner that the through electrode 58 is formed at a position on the rear surface of the second silicon layer 53 where the through electrode 58 is required to be formed. Publicly known photolithography is used for patterning, for example. A publicly known photoresist is used for the resist film 46. Alternatively, an oxide film or a nitride film subjected to patterning after being formed may be used for the resist film 46.

Next, a recessed portion 55 is formed on the rear surface of the second silicon layer 53 (refer to FIG. 11F). The recessed portion 55 is a hole passing through the second silicon layer 53 until reaching the common wire 54 in the silicon oxide layer 51. Accordingly, a bottom portion of the recessed portion 55 corresponds to a partial region of the common wire 54. For example, dry etching using gas having reactivity with silicon (Si) such as SFr (sulfur hexafluoride) is used in forming the recessed portion 55.

Next, an insulation film 56 (for example, SiO₂) is layered on an inner wall of the recessed portion 55 (refer to FIG. 11G). With this, a substrate layered with the insulation film 56 is obtained. For example, chemical vapor deposition (CVD) is used for the insulation film 56. Next, a region of the insulation film 56 corresponding to the bottom portion of the recessed portion 55 is subjected to the photolithography and thereafter patterned with a resist film 48 (refer to FIG. 11H), which is then removed through etching (refer to FIG. 11I). As a result, a state where the insulation film 56 is formed on the inner wall of the recessed portion 55 other than a region in contact with the common wire 54 is obtained.

Next, a barrier layer and a seed layer 70 are formed as films on the insulation film 56 through sputtering (refer to FIG. 12A). Next, patterning 72 is carried out using the photolithography in order to obtain the through electrode 58 by plating and filling (refer to FIG. 12B). Subsequently, the recessed portion 55 is plated and filled through Cu plating or the like, thereby forming the through electrode 58 (refer to FIG. 12C).

A solder mask 61 is patterned on a most surface on the rear surface side of the second silicon layer 53 with the insulation film 56, the barrier layer along with the seed layer 70, the through electrode 58, and so forth interposed therebetween (refer to FIG. 12D). Next, a bump 62 is formed at a portion where the through electrode 58 is exposed (refer to FIG. 12E).

The aforementioned processes in FIG. 11D to FIG. 11I, FIG. 12A to FIG. 12E are implemented to carry out the process of processing the first substrate 32A and then obtaining the photo detection layer 32.

Next, a process of removing the supporting substrate 44 is carried out (refer to FIG. 12F). The layered body 80 is formed through this process. For example, UV light irradiation is used to remove the supporting substrate 44.

Here, the supporting substrate 44 is bonded to the photo detection layer 32 with the first member 30 interposed therebetween. Accordingly, the occurrence of damage to the photo detection element 14 in the photo detection layer 32 and a crystal defect therein can be suppressed while the supporting substrate 44 is removed.

Next, the photodetector 10 is cut across the surrounding regions 11B in the layered direction to be separated into the individual pixel regions 11A through dicing (refer to FIG. 12G). At this state, the first member 30 is bonded to the surrounding region 11B on the light incident surface 11 of the photo detection layer 32 in the photodetector 10 with the first adhesive layer 34A interposed therebetween.

Next, the photo detection layer 32 is mounted on an arbitrary mounted substrate 36 with an electrode 63, which is obtained through reflow or the like, interposed therebetween. As a result, the photo detection layer 32 and the mounted substrate 36 are electrically and mechanically connected to each other (refer to FIG. 12H).

Next, the second process is carried out. In detail, the light conversion member 18 is inserted into the through hole 30A of the first member 30 and arranged so as to oppose the pixel region 11A (refer to FIG. 13). Specifically, a second adhesive layer 34B is disposed on the pixel region 11A in the photo detection layer 32. Thereafter, the light conversion member 18 is inserted into the through hole 30A and then, an end portion of the light conversion member 18 on an upstream side in an insertion direction is bonded to the second adhesive layer 34B. For example, a thermosetting type adhesive is used for the second adhesive layer 34B. Through this second process, the light conversion member 18 is arranged so as to oppose each of the pixel regions 11A with the second adhesive layer 34B interposed therebetween.

The first process and the second process described above are implemented to manufacture the photodetector 10.

As described above, the method for manufacturing the photodetector 10 according to the embodiment includes the first process and the second process. The first process is a process of forming the layered body 80 (refer to FIG. 12F) in which the first member 30 protruding toward the opposite side of the light incident surface 11 is arranged on at least a portion of the surrounding region 11B in the photo detection layer 32. The second process is a process of arranging the light conversion member 18 such that the light conversion member 18 opposes each of pixel regions 11A in the photo detection layer 32 with the adhesive layer 34 interposed therebetween (refer to FIG. 13).

As described above, in the method for manufacturing the photodetector 10 according to the embodiment, after the layered body 80 in which the first member 30 is arranged on the photo detection layer 32 is formed, the light conversion member 18 is arranged so as to oppose the pixel region 11A. Accordingly, the light conversion member 18 can be easily and accurately arranged so as to oppose the pixel region 11A in the photo detection layer 32 with a simple configuration. In addition, the first member 30 is arranged on the photo detection layer 32 and thus, the improvement of the easiness in treating the photo detection layer 32 (handling property) during manufacturing can be achieved.

Consequently, the photodetector 10 manufactured using the method for manufacturing the photodetector 10 according to the embodiment can suppress the deterioration of the detection accuracy of the photo detection element 14.

Meanwhile, in the method for manufacturing the photodetector 10 according to the embodiment, the first process includes the following processes. Specifically, first in the first process, a process of forming the first substrate 32A is carried out (refer to FIG. 11A). Next, a process of arranging the first member 30 including the through hole 30A corresponding to each of the pixel regions 11A on the side of the light incident surface 11 of the first substrate 32A is carried out (refer to FIG. 11B). Thereafter, a process of bonding the supporting substrate 44 on the side of the light incident surface 11 of the first substrate 32A with the first member 30 interposed therebetween is carried out (refer to FIG. 11D). Subsequently, a process of obtaining the photo detection layer 32 by processing the first substrate 32A is carried out (refer to FIG. 11E to FIG. 11I and FIG. 12A to FIG. 12E). Next, a process of removing the supporting substrate 44 is carried out (refer to FIG. 12F).

Furthermore, in the second process, a process of inserting the light conversion member 18 into the through hole 30A of the first member 30 and arranging the light conversion member 18 such that the light conversion member 18 opposes each of the pixel regions 11A with the adhesive layer 34 interposed therebetween is carried out (refer to FIG. 13). These processes are implemented to manufacture the photodetector 10.

As described above, in the method for manufacturing the photodetector 10 according to the embodiment, the supporting substrate 44 used for the reinforcement and the protection of the photo detection layer 32 during manufacturing is bonded to the photo detection layer 32 with the first member 30 interposed therebetween. Subsequently, the photo detection layer 32 is processed in a state where the supporting substrate 44 is bonded thereto. Thereafter, the supporting substrate 44 that has been bonded to the first member 30 is removed from the first member 30. As a result, the occurrence of damage to the photo detection element 14 and a crystal defect therein can be suppressed while the supporting substrate 44 is removed. In addition, because it is not necessary to configure the photodetector 10 as including the supporting substrate 44, the photodetector 10 in which the occurrence of crosstalk is suppressed can be manufactured.

Meanwhile, in the method for manufacturing the photodetector 10 according to the embodiment, the light conversion member 18 is inserted into the through hole 30A of the first member 30 corresponding to the pixel region 11A, whereby the light conversion member 18 is arranged so as to oppose the pixel region 11A. As a result, the first member 30 functions as a guide when the light conversion member 18 is bonded. Accordingly, the light conversion member 18 can be easily and accurately arranged so as to oppose the pixel region 11A in the photo detection layer 32 with a simple configuration. In addition, the improvement of the easiness in treating the photo detection layer 32 (handling property) during manufacturing can be achieved.

Consequently, the photodetector 10 manufactured using the method for manufacturing the photodetector 10 according to the embodiment can suppress the deterioration of the detection accuracy of the photo detection element 14.

### Third Embodiment

The second embodiment has described a case where the first member 30 including the through hole 30A is arranged on the side of the light incident surface 11 of the first substrate 32A (refer to FIG. 11B).

Alternatively, a through hole 30A may be formed after a plate-shaped member having a plate shape, which is formed of a constituent material of a first member 30, is arranged on a light incident surface 11 of a first substrate 32A.

In this case, a process of forming a photo detection layer 32 is first carried out in the aforementioned first process. Subsequently, a process of bonding the plate-shaped member having a plate shape on the side of the light incident surface 11 of the photo detection layer 32 is carried out. The plate-shaped member is at least required to be a member having a plate shape and formed of a constituent material of the first member 30.

Thereafter, the through hole 30A is formed at a region of this plate-shaped member corresponding to each of the pixel regions 11A, whereby the first member 30 is obtained. Dicing, wet etching, dry etching, sandblasting, and the like are used in forming the through hole 30A.

In this case, the through hole 30A is not limited to a shape passing through in the thickness direction and may be structured so as to be thinly maintained on the pixel region 11A (for example, a layer thickness of 30 μm or less).

Subsequently, by inserting the light conversion member 18 into the through hole 30A of the first member 30, the light conversion member 18 is arranged so as to oppose each of the pixel regions 11A in the photo detection layer 32.

The photodetector 10 may be manufactured in this manner.

The photo detection layer 32 may be formed by processing the first substrate 32A after the plate-shaped member is bonded to the first substrate 32A.

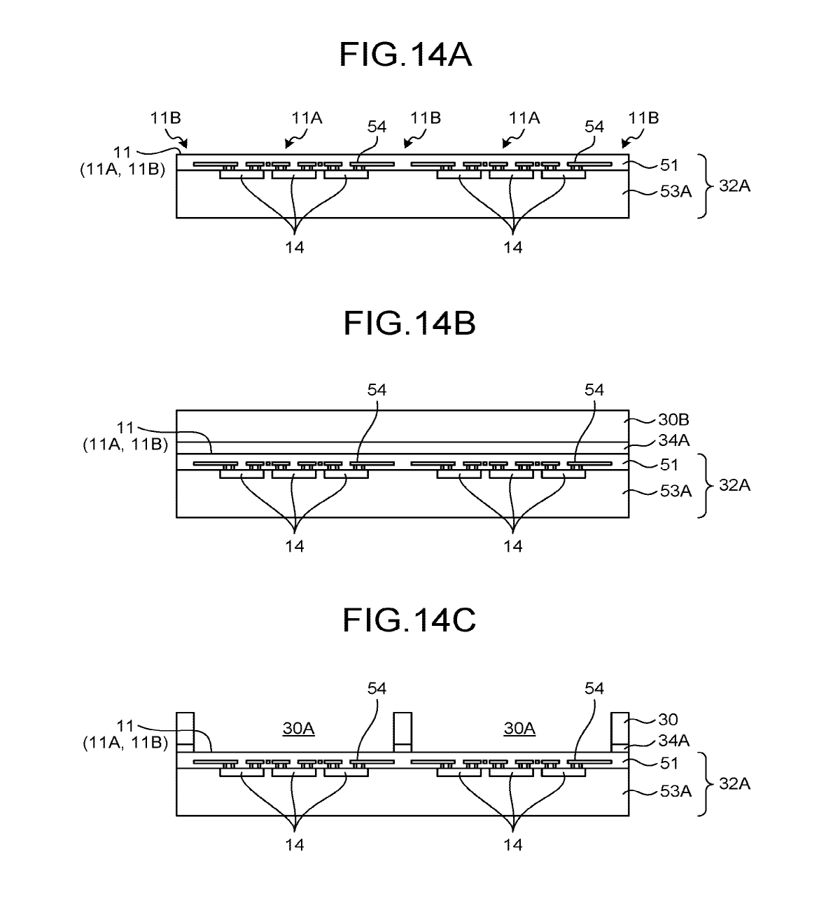

FIG. 14A to FIG. 14C are explanatory views for a method for manufacturing a photodetector 10 according to the embodiment. First, as in the second embodiment (refer to FIG. 11A), a process of forming the first substrate 32A is carried out (refer to FIG. 14A).

Next, a process of bonding a plate-shaped member 30B having a plate shape, which is formed of a constituent material of the first member 30, on the side of the light incident surface 11 of the first substrate 32A with a first adhesive layer 34A interposed therebetween is carried out (refer to FIG. 14B).

Thereafter, a process of forming the through hole 30A at a region of the plate-shaped member 30B corresponding to each of the pixel regions 11A to obtain the first member 30 is carried out (refer to FIG. 14C).

Following this, as in the second embodiment, a process of bonding a supporting substrate 44 on the side of the light incident surface 11 of the first substrate 32A with the first member 30 interposed therebetween is carried out (refer to FIG. 11D). Subsequently, a process of obtaining the photo detection layer 32 by processing the first substrate 32A is carried out (refer to FIG. 11E to FIG. 11I and FIG. 12A to FIG. 12E). Next, a process of removing the supporting substrate 44 is carried out (refer to FIG. 12F). Furthermore, as the second process, a process of inserting the light conversion member 18 into the through hole 30A of the first member 30 and arranging the light conversion member 18 such that the light conversion member 18 opposes each of the pixel regions 11A in the photo detection layer 32 is carried out (refer to FIG. 13). With this, the photodetector 10 is manufactured.

As described above, the through hole 30A may be formed after the plate-shaped member 30B having a plate shape, which is formed of a constituent material of the first member 30, is arranged on the light incident surface 11 of the first substrate 32A.

### Fourth Embodiment

In the embodiment, a different manufacturing method from that of the second embodiment for the photodetector 10 described in the first embodiment will be described.

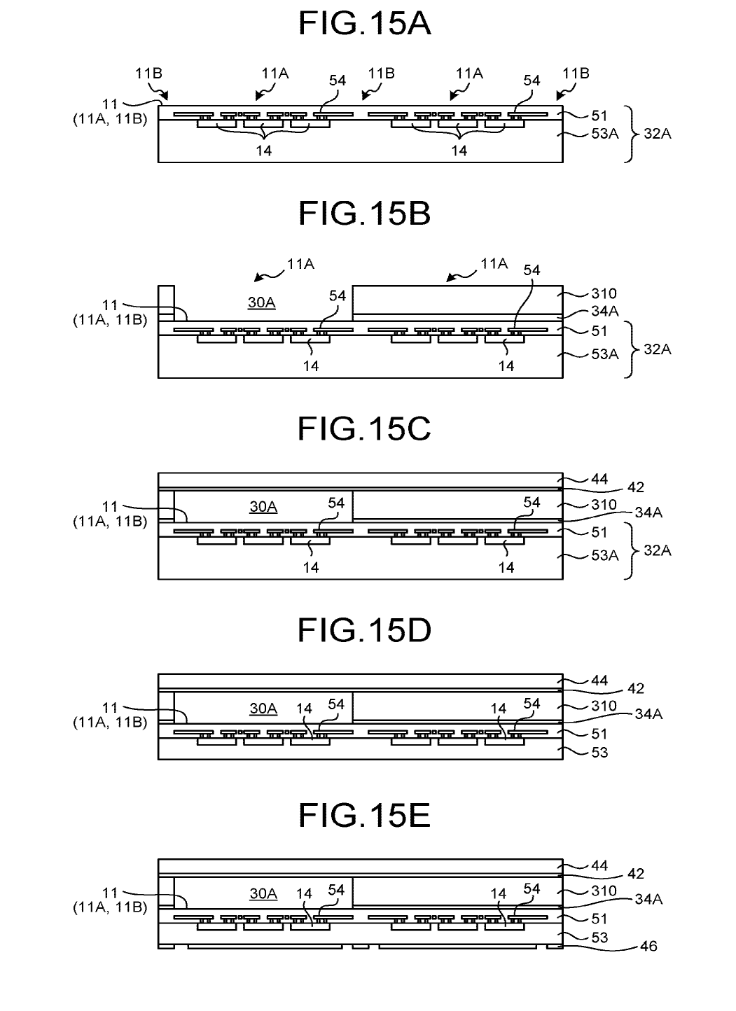

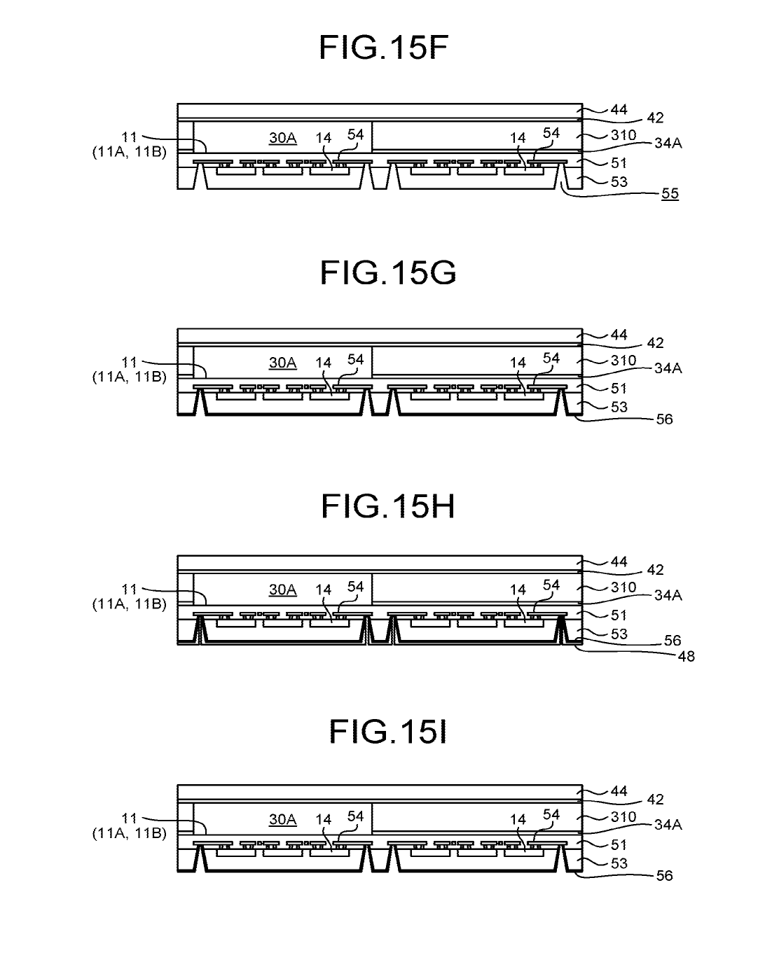

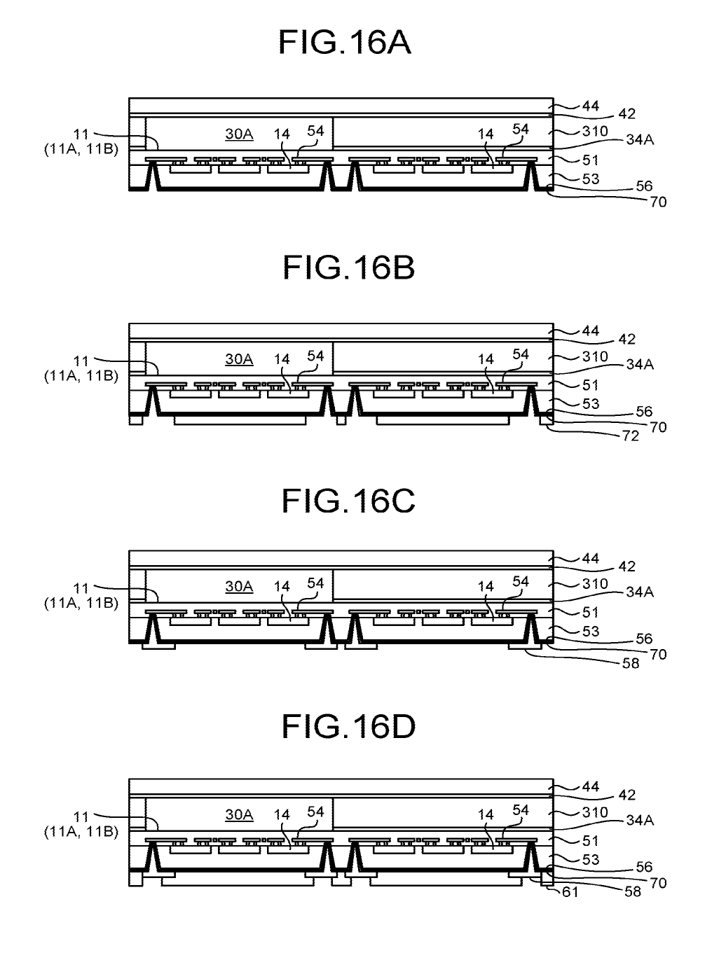

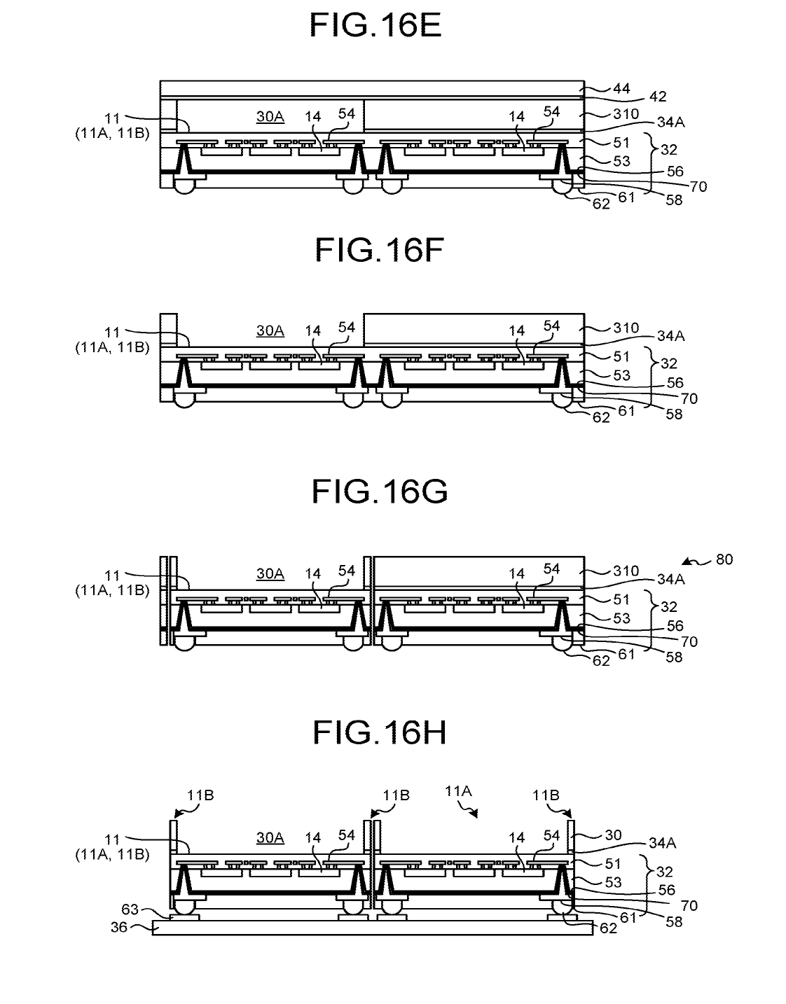

FIG. 15A to FIG. 15I and FIG. 16A to FIG. 16H are explanatory views for an example of a method for manufacturing a photodetector 10 according to the embodiment. Sections similar to those in the method for manufacturing the photodetector 10 described in the second embodiment will be denoted with similar reference numerals and the description thereof will be omitted.

First, multiple processes (FIG. 15A to FIG. 15I, FIG. 16A to FIG. 16H) are carried out as the first process.

As illustrated in FIG. 15A, a publicly known CMOS process is used first to carry out a process of forming, on a light incident surface 11, a first substrate 32A including a pixel region 11A and a surrounding region 11B. This process is similar to the process illustrated in FIG. 11A.

Next, as illustrated in FIG. 15B, a second member 310 provided with through holes 30A having shapes similar to those of the pixel regions 11A at regions corresponding to some of the plurality of pixel regions 11A is prepared.

The second member 310 is a member to be configured as a first member 30 through a process described later. For this reason, the second member 310 is made of a material similar to that of the first member 30. In addition, a method for forming the through hole 30A is similar to that of the second embodiment.

The second member 310 is provided with the through holes 30A at regions corresponding to some of the plurality of pixel regions 11A in the first substrate 32A. In other words, the second member 310 does not have the through holes 30A at regions corresponding to some of the plurality of pixel regions 11A in the first substrate 32A. Accordingly, when the second member 310 is bonded to the first substrate 32A, a bonding area of the second member 310 to the first substrate 32A is larger than the case of the first member 30.

Next, a process of arranging the second member 310 on the light incident surface 11 of the first substrate 32A with a first adhesive layer 34A interposed therebetween is carried out (refer to FIG. 15B).

Thereafter, a process of bonding a supporting substrate 44 on the side of the light incident surface 11 of the first substrate 32A with the second member 310 and an adhesive layer 42 interposed therebetween is carried out (refer to FIG. 15C).

Subsequently, a process of obtaining a photo detection layer 32 by processing the first substrate 32A is carried out (refer to FIG. 15D to FIG. 15I and FIG. 16A to FIG. 16E). This process is similar to the process described in the second embodiment with reference to FIG. 11D to FIG. 11I and FIG. 12A to FIG. 12E.

Next, a process of removing the supporting substrate 44 is carried out (refer to FIG. 16F). For example, UV light irradiation is used to remove the supporting substrate 44.

Here, the supporting substrate 44 is bonded to the photo detection layer 32 with the second member 310 interposed therebetween. In the case of the second member 310, the smaller number of the through holes 30A is formed than the case of the first member 30. Accordingly, compared to the case of the first member 30, a large bonding area to the side of the photo detection layer 32 with the first adhesive layer 34A interposed therebetween is obtained in the case of the second member 310. As a result, in the method for manufacturing the photodetector 10 according to the embodiment, the occurrence of damage to the photo detection element 14 in the photo detection layer 32 and a crystal defect therein can be further suppressed while the supporting substrate 44 is removed.

Next, by cutting at the surrounding regions 11B in the layered direction, the separation into the individual pixel regions 11A is carried out through dicing (refer to FIG. 16G).

Thereafter, the photo detection element for which the through hole 30A is formed, that is, the photo detection element for which an aperture is formed on top of the photo detection layer 32 is selected to be mounted on a mounted substrate 36 (refer to FIG. 16H). When mounted, the elements are arrayed in a matrix form on the mounted substrate 36. Because the through hole 30A is formed, the first member 30 can be bonded to the surrounding region 11B on the light incident surface 11 of the photo detection layer 32 in the photodetector 10 with the first adhesive layer 34A interposed therebetween.

Next, the photo detection layer 32 is mounted on an arbitrary mounted substrate 36 with an electrode 63, which is obtained through reflow or the like, interposed therebetween. As a result, the photo detection layer 32 and the mounted substrate 36 are electrically and mechanically connected to each other (refer to FIG. 16H).

Furthermore, as the second process, the light conversion member 18 is inserted into the through hole 30A of the first member 30 and the light conversion member 18 is arranged so as to oppose the pixel region 11A (refer to FIG. 13). The second process of arranging the light conversion member 18 is similar to that of the second embodiment.

As described thus far, in the first process of the method for manufacturing the photodetector 10 according to the embodiment, a process of forming the first substrate 32A is first carried out (refer to FIG. 15A). Next, a process of arranging, on the light incident surface 11 of the first substrate 32A, the second member 310 including the through holes 30A at regions corresponding to some of the plurality of pixel regions 11A is carried out (refer to FIG. 15B). Thereafter, a process of bonding the supporting substrate 44 on the side of the light incident surface 11 of the first substrate 32A with the second member 310 interposed therebetween is carried out (refer to FIG. 15D). Subsequently, a process of obtaining the photo detection layer 32 by processing the first substrate 32A is carried out (refer to FIG. 15E to FIG. 15I and FIG. 16A to FIG. 16E). Next, a process of removing the supporting substrate 44 is carried out (refer to FIG. 16F). Following this, a process of forming the through hole 30A at a region of the second member 310 where no through hole 30A corresponding to the pixel region 11A is present and thereby obtaining the first member 30 is carried out (refer to FIG. 16H).

Furthermore, as the second process, a process of inserting the light conversion member 18 into the through hole 30A of the first member 30 and arranging the light conversion member 18 such that the light conversion member 18 opposes each of the pixel regions 11A in the photo detection layer 32 with the adhesive layer 34 interposed therebetween is carried out (refer to FIG. 13). These processes are implemented to manufacture the photodetector 10.

As described above, in the method for manufacturing the photodetector 10 according to the embodiment, the second member 310 is arranged on the light incident surface 11 of the first substrate 32A. The second member 310 includes the through holes 30A at regions corresponding to some of the plurality of pixel regions 11A. Thereafter, the supporting substrate 44 is bonded to the second member 310 and, after the photo detection layer 32 is processed, the supporting substrate 44 is removed from the second member 310.

In this manner, the embodiment uses the second member 310 having a larger bonding area to the side of the photo detection layer 32 than that of the first member 30. As a result, in the method for manufacturing the photodetector 10 according to the embodiment, the occurrence of damage to the photo detection element 14 and a crystal defect therein can be further suppressed than the case of the second embodiment while the supporting substrate 44 is removed. In addition, the further improvement of the easiness in treating the photo detection layer 32 (handling property) during manufacturing can be achieved.

Meanwhile, compared to the case of the first member 30, the second member 310 has a large bonding area to the side of the photo detection layer 32. As a result, the generation of a warp in the photo detection layer 32 can be suppressed by implementing the manufacturing process, whereby the enhancement of the flatness of the photo detection layer 32 can be achieved.

In the embodiment, the through hole 30A has been formed at a region of the second member 310 where no through hole 30A corresponding to the pixel region 11A is formed (refer to FIG. 16H). However, the through hole 30A may not be formed in this region of the second member 310. In this case, at a state after the separation into the individual pixel regions 11A is carried out, the photo detection layer 32 provided with the second member 310 for which the through hole 30A is not formed is simply excluded from the object on which the light conversion member 18 is to be mounted.

### Fifth Embodiment

Each of the aforementioned second to fourth embodiments has described a case including the process of removing the supporting substrate 44 during the manufacturing process. However, the embodiment does not include a process of removing a supporting substrate 44.

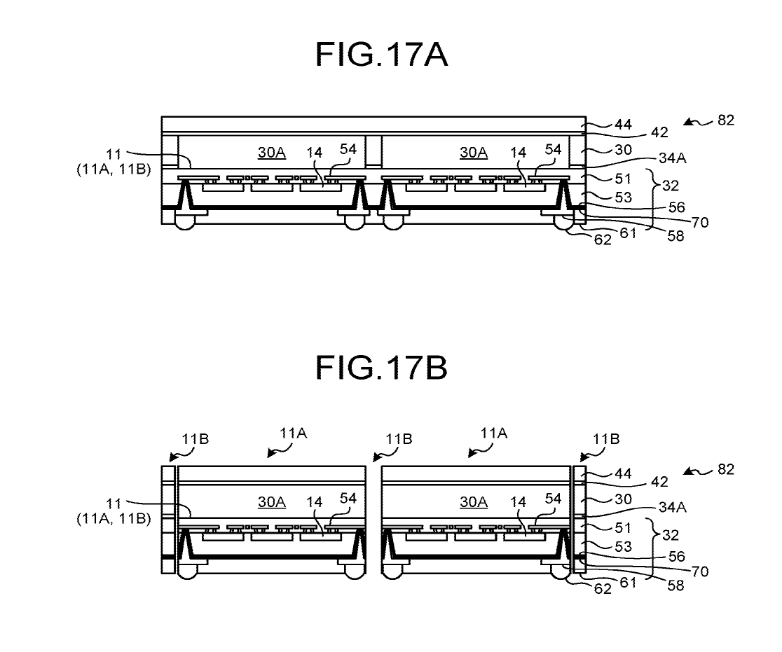

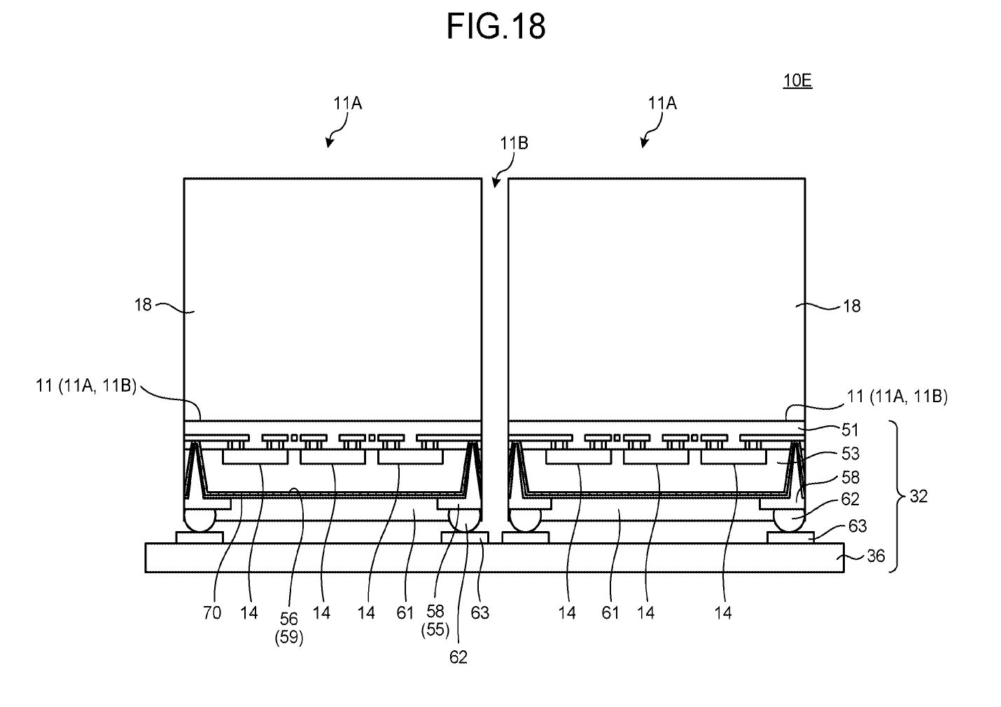

FIG. 17A and FIG. 17B are explanatory views for a method for manufacturing a photodetector 10E according to the embodiment (refer to FIG. 18).

First, as in the second embodiment, the first process is carried out. Specifically, a process of forming a first substrate 32A is first carried out (refer to FIG. 11A). Next, a process of arranging a first member 30 including a through hole 30A on a light incident surface 11 of the first substrate 32A is carried out (refer to FIG. 11B). Thereafter, a process of bonding the supporting substrate 44 on the side of the light incident surface 11 of the first substrate 32A with the first member 30 interposed therebetween is carried out (refer to FIG. 11D). Subsequently, a process of obtaining a photo detection layer 32 by processing the first substrate 32A is carried out (refer to FIG. 11E to FIG. 11I and FIG. 12A to FIG. 12E).

Following this, as illustrated in FIG. 17A, a layered body 82 is obtained by layering a first adhesive layer 34A, the first member 30, an adhesive layer 42, and the supporting substrate 44 on the photo detection layer 32 in this order. Next, a process of cutting this layered body 82 such that a pixel region 11A and a surrounding region 11B are separated from each other is carried out (refer to FIG. 17B).

For example, this cutting is carried out through dicing. In detail, after a dicing tape is affixed on the supporting substrate 44, the dicing is carried out from the side of the photo detection layer 32 in the layered body 82.

Here, the first member 30 is bonded on the surrounding region 11B. Accordingly, when this process of cutting is carried out, a state where the first member 30 is separated from the pixel region 11A is obtained. Additionally, because the supporting substrate 44 is bonded to the first member 30, a state where the supporting substrate 44 is separated from the photo detection layer 32 is obtained when this process of cutting is carried out. As a result, a state where the first member 30 and the supporting substrate 44 are separated from the photo detection layer 32 is obtained.

Furthermore, as the second process, a process of arranging a light conversion member 18 such that the light conversion member 18 opposes each of the pixel regions 11A in the photo detection layer 32 is carried out (refer to FIG. 18). FIG. 18 is an explanatory view for the photodetector 10E. These processes are implemented to manufacture the photodetector 10E.

As described above, the embodiment does not include the process of removing the supporting substrate 44 while the photodetector 10E is formed. As a result, the occurrence of damage to the photo detection element 14 and a crystal defect therein can be suppressed while the supporting substrate 44 is removed. In addition, because it is not necessary to configure the photodetector 10 as including the supporting substrate 44, the occurrence of crosstalk can be suppressed.

Consequently, the photodetector 10E manufactured using the method for manufacturing the photodetector 10E according to the embodiment can suppress the deterioration of the detection accuracy of the photo detection element 14.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photodetector comprising:
a photo detection layer including, on a light incident surface on which light is incident,
a plurality of pixel regions each holding a photo detection element configured to detect the light, and
a surrounding region that is a region other than the pixel regions on the light incident surface;
a plurality of light conversion members that is arranged so as to oppose the pixel regions in the photo detection layer and is configured to convert radiation to the light, each of the light conversion members including a bottom surface opposing the pixel region in the photo detection layer, a top surface opposing the bottom surface, and a lateral surface connecting the bottom surface and the top surface; and
a first member that is disposed on at least a portion of the surrounding region on the light incident surface and covers a portion of the lateral surface of the light conversion member.

2. The photodetector according to claim 1, wherein
the first member is disposed on a downstream side of the pixel region in a first direction in the surrounding region, and
the first direction is a direction in which force is applied to the photo detection element when the photodetector is driven in a predetermined direction.

3. The photodetector according to claim 1, wherein
the first member encloses circumference of each of the plurality of pixel regions.

4. The photodetector according to claim 1, wherein
a surface of the first member opposing the light conversion member has a shape in accordance with the light conversion member.

5. The photodetector according to claim 1, wherein
the first member includes a first portion covering a portion of the lateral surface of the light conversion member and a second portion disposed between the photo detection layer and the light conversion member, and
a thickness of the second portion is thinner than a thickness of the first portion.

6. The photodetector according to claim 5, wherein
the second portion has light transmission property.

7. The photodetector according to claim 1, wherein
a section of the first member covering the light conversion member has light reflectivity.

8. The photodetector according to claim 1, further comprising a reflection layer having light reflectivity and covering a section of the light conversion member not covered by the first member.

9. The photodetector according to claim 1, wherein
the length of the first member in a layered direction of the photo detection layer and the light conversion member is smaller than the length of the light conversion member in the layered direction.

10. A method for manufacturing a photodetector, comprising:
a first process of forming a layered body in which a first member covering a portion of a light conversion member configured to convert a radiation to light is arranged on at least a portion of a surrounding region in a photo detection layer including, on a light incident surface on which the light is incident, a plurality of pixel regions each holding a photo detection element configured to detect the light, and the surrounding region corresponding to a region other than the pixel regions on the light incident surface; and
a second process of arranging the light conversion member such that the light conversion member opposes each of the pixel regions with an adhesive layer interposed between the light conversion member and each of the pixel regions.

11. The method for manufacturing a photodetector according to claim 10, wherein
the first process includes:
forming a first substrate having the plurality of pixel regions and the surrounding region on the light incident surface;
arranging, on a side of the light incident surface of the first substrate, the first member having a through hole at a region corresponding to each of the plurality of pixel regions;
bonding a supporting substrate to the side of the light incident surface of the first substrate with the first member interposed between the supporting substrate and the first substrate;
forming the photo detection layer by processing the first substrate; and
removing the supporting substrate, and
the second process includes inserting the light conversion member into the through hole of the first member to arrange the light conversion member such that the light conversion member opposes each of the pixel regions with the adhesive layer interposed between the light conversion member and each of the pixel regions.

12. The method for manufacturing a photodetector according to claim 10, wherein
the first process includes:
forming a first substrate having the plurality of pixel regions and the surrounding region on the light incident surface;
arranging, on a side of the light incident surface of the first substrate, a second member having through holes at regions corresponding to some of the plurality of pixel regions;
bonding a supporting substrate to the side of the light incident surface of the first substrate with the second member interposed between the supporting substrate and the first substrate;
forming the photo detection layer by processing the first substrate;
removing the supporting substrate; and
forming the first member by forming the through hole at a region of the second member where no through hole corresponding to the pixel region is present, and
the second process includes inserting the light conversion member into the through hole of the first member to arrange the light conversion member such that the light conversion member opposes each of the pixel regions with the adhesive layer interposed between the light conversion member and each of the pixel regions.

13. The method for manufacturing a photodetector according to claim 10, wherein
the first process includes:
forming a first substrate having the plurality of pixel regions and the surrounding region on the light incident surface;
arranging, on the side of the light incident surface of the first substrate, the first member having a through hole at a region corresponding to each of the plurality of pixel regions;
bonding a supporting substrate to the side of the light incident surface of the first substrate with the first member interposed between the supporting substrate and the first substrate;
forming the photo detection layer by processing the first substrate; and
cutting the layered body composed of the photo detection layer, the first member, and the supporting substrate such that the layered body is separated into the pixel region and the surrounding region.

14. The method for manufacturing a photodetector according to claim 10, wherein
the first process includes:
forming the photo detection layer;
bonding a plate-shaped member to the side of the light incident surface of the photo detection layer; and
forming the first member by forming a through hole at a region of the plate-shaped member corresponding to each of pixel regions, and
the second process includes inserting the light conversion member into the through hole of the first member and arranges the light conversion member such that the light conversion member opposes each of the pixel regions with the adhesive layer interposed between the light conversion member and each of the pixel regions.
